(19) United States
(12) Patent Application Publication
(10) Pub. No.: US 2026/0213480 A1
(43) Pub. Date: Jul. 23, 2026

(54) QUICK METER CONNECT ELECTRIC CHARGING SYSTEM

(71) Applicant: Kevin John Ferree, La Mesa, CA (US)

(72) Inventor: Kevin John Ferree, La Mesa, CA (US)

(21) Appl. No.: 19/429,312

(22) Filed: Dec. 22, 2025

Related U.S. Application Data
(63) Continuation-in-part of application No. 18/362,647, filed on Jul. 31, 2023, now Pat. No. 12,504,451.
Application No. 18/362,647 is a continuation of application No. 17/216,612, filed on Mar. 29, 2021, now Pat. No. 11,715,921.

(51) Int. Cl. H01R 31/06; B60L 53/16; B60L 53/60; G01R 22/06; H01R 13/713

(52) U.S. Cl. CPC H01R 31/065; B60L 53/16; B60L 53/60; G01R 22/065; H01R 13/7135; H01R 2201/20; H01R 2201/26

(57) ABSTRACT

A removable electrical meter quick connect device has a housing with a first face configured with connectors to mate to an electrical service panel in a meter connection manner, and a second face with an electrical meter, or connectors to mate to an electrical meter. With power lines connecting within. At least one breaker switch or breaker switch receptacle is on the housing and coupled to the power lines. Additional set(s) of lines are connected to the breaker switch(es) and exit a side of the housing to provide an external source of power (in/out) via the device, without requiring typical electrical panel work. Additional external devices are connected to the external power, wherein electrical vehicle charging is one of many possible devices.

### CROSS-REFERENCE TO RELATED APPLICATION(S)

This application is a Continuation-in-Part and claims the priority and benefit of U.S. non-provisional patent application Ser. No. 18/362,647 , filed Jul. 31, 2023 which is a CIP of U.S. non-provisional patent application Ser. No. 17/215,612 , filed Mar. 29, 2021, issued as U.S. Pat. No. 11,715,921, on Aug. 1, 2023, the contents of which are hereby incorporated by reference in their entirety.

### FIELD

This invention relates to electric charging directly from the meter side. More particularly, it relates to a device that can be easily installed onto a utility panel's meter connection to allow interfacing with an electric automobile for the purpose of charging, as well as to associated devices and systems connected to the exemplary device.

### BACKGROUND

With the popularity of electric vehicles, and external (outside house) appliances, more and more owners are installing chargers in their homes, apartments, condominiums and businesses to charge their vehicles, etc. This requires several hours of services by an electrician to rewire electrical panels, install outlets, conduits, run cables, cut and core through walls as well as attach an Electric Charger to a wall somewhere. Typically, this effort is considered a custom job and can be several thousands of dollars, not including the cost of the charger. Further, once the home is sold, the owner usually does not wish to invest more money to remove the charger, often leaving it for the next owner who may not have an electric car. Therefore, it would be beneficial to have a standardized device that easily interfaces with the standardized electrical utility meter system and is simple to install or remove, to achieve the same end.

To that effect, various methods and systems are described below that enable the rapid quick installation of a simple and relatively inexpensive interfacing device to the “house's” metering system to enable “separate-from-home” charging capabilities applicable to an electric car as well as other devices and systems.

### SUMMARY

The following presents a simplified summary in order to provide a basic understanding of some aspects of the claimed subject matter. This summary is not an extensive overview and is not intended to identify key/critical elements or to delineate the scope of the claimed subject matter. Its purpose is to present some concepts in a simplified form as a prelude to the more detailed description that is presented later.

In one aspect of the disclosed embodiments, an electrical quick meter connect device is provide, having an environmental housing with a first face is configured with connectors to mate directly to an electrical service panel in a meter connection manner, and a second face configured with connectors to mate directly to a utility meter in an electrical service panel connection manner; a first and second set of lines, internal to the housing, coupled to the first face to the second face; at least one breaker switch integral to and disposed on an external side of the housing and coupled to at least one of the first and second set of lines; and at least one external power line coupled to the at least one breaker switch and exiting the housing providing at least one of external power output and input to at an externally located device, wherein the quick meter connect device is configured to be inserted directly between a meter and electrical service panel to provide external power connection.

In another aspect of the disclosed embodiments, the device further comprises an environmentally secure power line coupler between the at least one breaker switch and the at least one external power line, enabling the external power line to be removably coupled from the quick meter connect device and/or at least one of a timer, clock, wireless transmitter, cellular transceiver, computer, control board, surge protector, Wi-fi, cellular repeater, satellite transceiver, Bluetooth® device, control buttons, data communication port, display, and near field sensor is coupled to at least one of the first and second set of lines and/or at least one of a timer, clock, wireless transmitter, cellular transceiver, computer, control board, surge protector, Wi-fi, cellular repeater, satellite transceiver, Bluetooth® device, control button, data communication port, display, and near field sensor are disposed within the externally located device and/or a replaceable antenna module, a tamper sensor and temperature sensor, wherein at least one of control, diagnostics, system monitoring, boosting, and over-the-air firmware updates are facilitated through the replaceable or internal antenna module and/or a lockable weatherproof cover over the at least one breaker switch and the environmentally secure power line coupler and/or wherein the externally located device is a charging station and a charging cable is connected to the charging station and/or wherein the charging cable is adapted to conform to at least one of a Type 1, 2, 3, 5 Pin, 7 Pin, 9 pin, J17782, North American Charging Standard (NACS), Combined Charging System (CCS), Combo 1/2(CCS1/2 ), and Supercharger and/or wherein the environmentally secure power line coupler is at least one of a contact and non-contact charging cord attachment assembly with at least one of a quick-release and breakaway functionality and/or further comprising an integrated utility connected meter and/or wherein at least one of single-phase, 3-phase power, 120V, 240V, 208V, 277V, 480V, 600V, and breaker-limited amperage is provided to the at least one external power line and/or at least one of a charging station for an electrical vehicle, a drop box, and a drone charger, wherein there is a low voltage line between the at least one charging station for an electrical vehicle and the electrical vehicle and/or wherein the drop box has an access-controllable entry and/or a control system, containing at least one of a real-time current-sensing element, a controller board, and a switching relay, wherein the control system is configured to monitor load capacity of an electrical service panel and dynamically limit current flow to the at least one external power line and/or wherein the controller board is configured to monitor panel load and regulate current in accordance with a predetermined panel capacity allowance and/or a quick meter connect device coupler, coupling one side of the quick meter connect device to an electrical service panel and/or wherein the quick meter connect device coupler is at least one of a circular strap, seal tight conduit, a sealing ring, and electrical cord having at least one of a hole, a magnetic anchor, a screw, a nail, a mechanical latch, and an adhesive to secure the quick meter connect device and/or at least one of a ground connection and a label coupled to the quick meter connect device coupler and/or at least one of a manual and automatic transfer switch and/or at least one of an electric car, solar panel, wind turbine, generator, battery storage, sub-panel, reactance bank, capacitors, inductors, chokes, grid, and inverter, connected to the at least one manual and automatic transfer switch and/or a plurality of remote devices connected in at least one of series and parallel to the at least one external power line.

In another aspect of the disclosed embodiments, the electric vehicle charging interface device is provided, having a meter-side electrical interface configured to couple directly to a utility revenue meter socket; a load-side electrical interface configured to supply power to an electrical panel or electric vehicle charging equipment; a controllable power circuit disposed between the meter-side electrical interface and the load-side electrical interface; and a controller configured to selectively authorize, limit, or interrupt electrical power delivery through the controllable power circuit in response to at least one of a utility control signal, a load condition, or a safety condition.

In yet another aspect of the disclosed embodiments, an electric vehicle charging coordination system is providing, having a plurality of electric vehicle charging interface devices (EVCID), each EVCID configured to control electrical power delivery to an electric vehicle, wherein at least one EVCID of the plurality of the EVCIDs is coupled directly to a utility revenue meter socket and has a controllable current interrupt switch on an outer surface; a platform server configured to communicate with the plurality of EVIDs; and a resource management software executed by the platform server, wherein the resource management software is configured to at least one of receive charging requests, determine authorization conditions based on at least one of grid capacity, utility policy, and safety constraints, and selectively cause electrical power delivery to be enabled or disabled at one or more of the EVIDs.

In yet another aspect of the disclosed embodiments, a method of coordinating electric vehicle charging has the steps of receiving, at a platform system, a request to initiate electric vehicle charging; evaluating one or more authorization conditions associated with at least one of an electrical grid capacity, utility requirements, and safety constraints; and transmitting a control instruction to an intermediary charging interface (ICI) coupled directly to a utility revenue meter socket the ICI having a controllable current interrupt switch on an outer surface of the ICI to selectively enable or disable electrical power delivery to the electric vehicle.

In yet another aspect of the disclosed embodiments, an electric vehicle charging interface device is provided, having a controllable power circuit disposed directly on a utility panel connection, having a meter attachment fixture or a meter integrated therein, and providing power to an electric vehicle charging load; a communication interface configured to exchange data with a platform system; and a controller configured to open or close the controllable power circuit in response to control instructions received from the platform system.

In another aspect of the disclosed embodiments, a method for managing electrical current in an electric power interface system, is provided having the steps of monitoring, by an interface system directly coupled to a utility power panel having a controllable breaker disposed on an exterior of the interface system and a communication-capable controller coupled to the breaker, real-time electrical load conditions; an available electrical capacity of the utility power panel based on the monitored real-time electrical load conditions; and dynamically regulating via the communication-capable controller a flow of electrical current through the interface system in real time in accordance with available electrical capacity.

In another aspect of the disclosed embodiments, the method also performs the step of determining an authorization condition to enable the flow of electrical current and/or wherein determining the available electrical capacity comprises subtracting a measured load from a predetermined panel capacity limit and/or wherein dynamically regulating the flow of electrical current comprises at least one of limiting, throttling, and modulating the flow of electrical current and/or receiving at least one of a demand response and load-shedding commands from a grid management system; and altering a condition state of the controllable breaker in response to the commands and/or altering a condition state of the controllable breaker in response to detection of the abnormal electrical condition.

In another aspect of the disclosed embodiments, an electrical meter-interface device has a housing configured to be installed between a utility revenue meter and a utility meter socket of an electrical service panel; a plurality of electrical conductors extending through the housing and configured to electrically couple the utility revenue meter to the utility meter socket; an overcurrent protection device mounted on an exterior of the housing and electrically coupled to at least one of the plurality of electrical conductors; and an external power interface electrically coupled to the overcurrent protection device and configured to supply electrical power to an externally located device, wherein the electrical meter-interface device provides external electrical power independent of branch circuit breakers within the electrical service panel.

In another aspect of the disclosed embodiments, an electrical meter-interface device has a housing configured to couple between a utility revenue meter and a utility meter socket; electrical conductors extending through the housing; an integral breaker receptacle disposed within the housing and electrically coupled to at least one of the electrical conductors; an external power interface electrically coupled to the integral breaker receptacle, wherein the integral breaker receptacle is configured to receive a removable circuit breaker selected to provide overcurrent protection for power delivered through the external power interface.

In another aspect of the disclosed embodiments, an electrical meter-interface device has a housing configured for installation between a utility revenue meter and a utility meter socket; electrical conductors extending through the housing; an overcurrent protection device coupled to at least one of the electrical conductors; and an environmentally sealed external receptacle mounted on the housing and electrically coupled to the overcurrent protection device, wherein the external receptacle is configured to provide electrical power to at least one external load without modification of the electrical service panel.

In another aspect of the disclosed embodiments, an electrical meter-interface device has a housing configured to couple between a utility revenue meter and a utility meter socket; electrical conductors extending through the housing; and an external power interface electrically coupled to the electrical conductors, wherein a meter coupling axis of the housing is laterally offset from a panel coupling axis of the housing such that an axial protrusion of the device from the electrical service panel is reduced.

In another aspect of the disclosed embodiments, an electrical power interface device has a housing configured to be installed at a utility meter connection; a controllable switching element disposed within the housing and electrically coupled to conductors supplying power through the housing; at least one electrical sensor configured to monitor a load condition of an associated electrical service panel; and a controller configured to dynamically regulate current flow through the controllable switching element based on an available electrical capacity of the electrical service panel.

In another aspect of the disclosed embodiments, an electrical meter-interface device has a housing configured to be installed between a utility revenue meter and a utility meter socket; overcurrent protection device supported by the housing and connected to electrical conductors within the housing; an external power interface coupled to the overcurrent protection device; and a breakaway coupling configured to mechanically release an external power cable from the housing when subjected to a tensile load above a threshold, wherein release of the breakaway coupling interrupts electrical power delivery through the external power interface.

In yest another aspect of the disclosed embodiments, the device's breakaway coupling comprises at least one of a magnetic coupling, snap-fit coupling, latching coupling, or twist-release coupling and/or wherein the breakaway coupling is configured such that mechanical separation of the external power cable occurs prior to transfer of damaging force to electrical terminations within the housing and/or has a cable support assembly coupled to the housing and configured to provide strain relief by supporting the external power cable and reducing tensile load transferred to the external power interface.

In another aspect of the disclosed embodiments, an electrical power interface device for installation at a service entrance of an electrical installation is provided, having a housing configured to be installed between a utility revenue meter and a meter socket of an electrical service panel; electrical conductors arranged within the housing for conducting electrical power between the utility revenue meter and the electrical service panel; an external power interface electrically coupled to at least one of the electrical conductors; an overcurrent protection device arranged between the electrical conductors and the external power interface; a mechanical breakaway coupling associated with the external power interface and configured to mechanically separate an external power cable when subjected to a tensile force exceeding a predetermined threshold; and an interruption mechanism configured such that mechanical separation of the breakaway coupling directly triggers electrical interruption of power flow to the external power interface at the service entrance, thereby preventing exposure of energized conductors and/or wherein the external power interface comprises a retractable electric vehicle charging cable assembly, the retractable electric vehicle charging cable assembly comprising: a charging cable electrically coupled to the external power interface; a retraction mechanism configured to selectively extend and retract the charging cable; and a cable termination configured to mate with an electric vehicle charging inlet and/or wherein the retraction mechanism comprises at least one of a spring-biased reel, motor-driven reel, gravity-assisted reel, or powered winding mechanism and/or wherein the retractable electric vehicle charging cable assembly is configured to at least one of maintain electrical disconnection when the charging cable is fully retracted and upon extension beyond a predetermined length enables electrical connection to the external power interface.

### BRIEF DESCRIPTION OF THE DRAWINGS

FIG. 1 is an exploded view of an exemplary Quick Meter Connect (QMC) device.

FIG. 2 is an internal wiring connection layout for an exemplary QMC device.

FIG. 3 is an exploded view of an exemplary QMC device connected to an electric vehicle.

FIGS. 4A-C are block diagram illustrations of alternative exemplary embodiments.

FIG. 5 is block diagram illustrating another exemplary QMC embodiment, wherein more than one breakers are situated on the side of the QMC device.

FIG. 6A is a simplified illustration of a main panel having a different QMC-to-Panel attachment paradigm via a locking “compression” sleeve.

FIG. 6B is a side-view illustration showing an implementation of the attachment paradigm of FIG. 6A

FIG. 7 is an illustration of various views of another attachment mechanism showing a ringless QMC meter extension.

FIG. 8 is an illustration of an exemplary embodiment of a breakerless QMC, wherein the externally accessible breaker (not shown) is not yet installed.

FIG. 9A is an illustration of an offset meter QMC.

FIG. 9B is an illustration of another offset meter QMC, where the meter mount point is on the left side, while the QMC panel mount point is on the right interior side.

FIG. 9C is an illustration demonstrating an offset QMC with Wi-Fi capability and/or cellular capability.

FIG. 10 is an illustration of an exemplary QMC having multiple breakers coupled to multiple output lines, one of which connects to an EV and the other to a reactance bank.

FIG. 11 is a simplified diagram illustrating the ability of a QMC to be connected via line to multiple different loads and/or sources, through a common junction or base.

FIG. 12 is an example of a modification of the embodiment of FIG. 11, wherein a shutoff or disconnect (optionally with monitoring capabilities) is positioned external to or downstream from the QMC.

FIG. 13 is an illustration of a multi-use QMC, having a plurality of breakers and attendant output/input lines, connected to respective loads and sources.

FIG. 14 is an illustration of an embodiment having a combination of features of various embodiments.

FIG. 15 is a schematic illustration of a single-phase, 2-breaker QMC, showing one set of possible connections to facilitate powering of first load and second load.

FIG. 16 is a schematic illustration of a three-phase, 2-breaker QMC, showing one set of possible connections to facilitate powering of first load and second load.

FIG. 17 is an illustration of an all-in-one QMC, with a built-in meter installed onto a panel.

FIG. 18 is side view illustration of the all-in-one QMC of FIG. 17 separate from a panel.

FIG. 19 is an illustration of an exemplary QMC having hard data ports.

FIG. 20 is an illustration of an exemplary QMC attached to a home and powering a drop box.

FIG. 21 is an illustration of an exemplary embodiment wherein residence is connected to QMC, connected directly or indirectly to incoming mains lines, which is supporting via a line a charging station.

FIG. 22 is an illustration of an exemplary QMC coupled via a power line to a multi-use charging station, both a charging capability and a drop box capability.

FIG. 23 is an illustration of an exemplary embodiment QMC coupled via power line to a stand-alone drone-facilitating automatic drop box, showing a drone delivering an item.

FIGS. 24A-D are different views of another exemplary QMC, some views showing optional elements/locations.

FIG. 24A is a front view of exemplary an QMC, showing four meter-side socket jaws or terminals for coupling to a standard utility meter.

FIG. 24B is a top view of the exemplary QMC of FIG. 24A with a slight modification.

FIG. 24C is a side view of the exemplary QMC of FIG. 24A with a variation in the location of locking elements.

FIG. 24D is a bottom view of the exemplary QMC of FIG. 24C but with the attachment ring(s) tightening features on the same sides.

FIG. 24E is a front view of the exemplary QMC of FIG. 24C but with waterproof receptacle enclosure having its securing “lock” disposed on the bottom.

FIG. 25 is a side view of an exemplary QMC displaying panel side stabs and the opposing jaws for coupling to a standard utility meter (not shown) and equipped with communication data booster/repeater.

FIG. 26 is an illustration showing an attachment ring with various features of a securing/locking mechanism.

FIG. 27 is a side view of an “all-in-one” exemplary QMC showing exposed panel side stabs and with a pre-attached (or integrated) utility meter, etc.

FIG. 28 is a side view of an exemplary QMC with an attached corded charger and a Control Board.

FIG. 29 is a side view of an exemplary QMC, similar to the embodiment of FIG. 28, however with a different “quick connect/disconnect” configuration.

FIG. 30A is a front perspective view of a 3-D rendered exemplary QMC.

FIG. 30B is aside view of a 3-D rendered exemplary QMC.

FIG. 30C is an opposing side of a 3-D rendered exemplary QMC.

### DETAILED DESCRIPTION

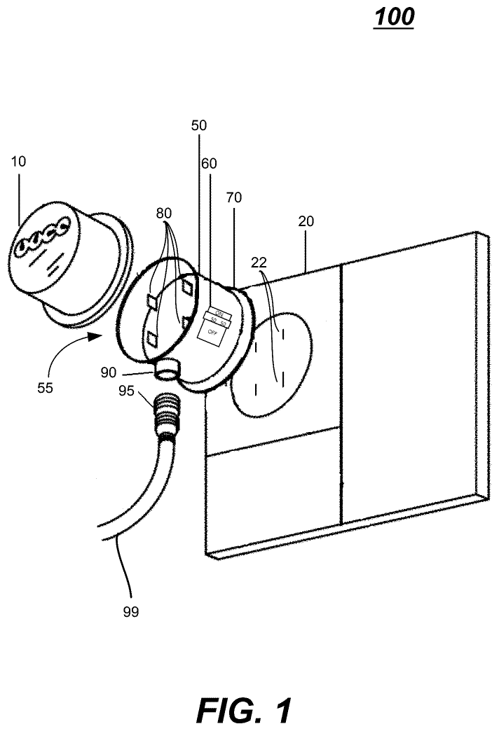

FIG. 1 is an exploded view illustration 100 of an exemplary Quick Meter Connect (QMC) device 55 for connection between an electric service utility meter 10 and electric panel/load center 20. Aspects of a utility meter 10 and electric panel 20 are well known in the art and therefore not further detailed herein, understanding that both the meter 10 and panel 20 contain contact elements, prongs, or receptacles (shown here for the panel 20 as elements 22) that physically mate to each other and provide electrical pathways between the two. The example being shown here is for a U.S. residential set-up having both 110 & 220 VAC connections. However, a non-residential configuration or international configurations can be implemented without departing from the spirit and scope of this disclosure.

The exemplary QMC device 55 has a protective housing 50 which contains on its front side corresponding front contact elements 80 that mirror the contacts 22 of the panel 20, so as to render itself electrically transparent to the meter 10. The housing 50 may be cylindrical as shown or may be of another shape, depending on implementation preference. The elements 80 are connected internally to breaker switch 60 for Over Current Protection and Ground Fault Protection, per the National Electric Codes (NEC) or other applicable safety code; and in turn connected to the panel's elements 22. Circuit breaker 60 can be part of QMC device 50 so as to be physically attached therefore non-removable and outfitted with a current limiting amperage switch based on panel and utility rating. Or circuit breaker 60 can be a commercially known brand and be removed and installed with a current limiting amperage switch based on panel and utility rating. Circuit breaker 60 will be of weatherproof design and functionality. The rear 70 of the QMC device 55 is fitted with rear contact elements (not shown) that mate to the panel's elements 22. Mounting and the electrical connection of the QMC device 55 to the panel 20 can be achieved through typical means such as used in industry for the meter 10, or via other means. Non-limiting examples for the electrical connections can be via metal jaws, insertable slots, screw-down connectors, friction, etc. Non-limiting examples for the mechanical connections can be through bolts, screws, screw-on, brackets, friction, etc. Also, a protective sleeve (not shown) may be utilized. It is understood that some electrical connection methods also provide mechanical connection functions.

QMC device 55 further includes a charging line coupler 90 that mates to charging line connector 95 at the end of conduit or charging line 99. The method for coupling can be via threaded connection, snap-in, etc. The coupler 90 can be configured for connection to various charging line brands. Coupler 90 can be a plug in style receptacle, for example, NEMA 14-50 with a weatherproof design. Coupler 90 may also be of a quick breakaway design to provide extra safety measures (e.g., magnetic, snap-in, tension, twist, etc.). A breakaway type coupler 90 can be set to mechanically release from the housing when subjected to a tensile load above a maximum threshold. Of course, some sort of power shutoff is to be implemented in such a scenario.

The breakaway feature seen here may be replicated in any of the following embodiments, according to design preference. It is noted here that in some embodiments, coupler 90 may be first facilitated for connection to a conduit or raceway that leads to a later-connected charging line 99, if the electric vehicle charging location is not near the meter 10 location. Also, in some embodiments, for safety reasons, when a breakaway incident is detected, current thorough the QMC device may be shut down or transferred prior to damaging forces to electrical terminations within in the QMC.

In operation, as the QMC device 55 allows connections to the load side of the meter 10, any current/voltage is passed from the panel 20 into the meter 10, passing through the QMC device 55 and any current/voltage used by the charging line 99 will be registered in the meter 10. Conversely, any current/voltage sourced from the charging line 99 will be reflected in the meter 10. With appropriate interconnections, the QMC device 55 can provide any phase, voltage, single or 3-phase 120/240V, 120V/208V, 277V/480V, 600V, etc. according to available input power configuration. As well as be sized for 2 and 3 pole, from 20-amps (for example) through 200/400/600 etc. amps. Thus, anywhere a utility meter is located, a QMC device 55 can be installed to provide auxiliary power/input/output. In other applications, the QMC 55 device may also be tapped to the utility side of the meter 10, therefore not registering the electric consumption by the charging system on the meter 10. By interfacing the QMC device 55 between the meter 10 and panel 20, using the pre-existing meter-to-panel connection setup, the QMC device 55 can be quickly and easily attached and detached, without requiring rewiring of the panel 20. Therefore, no damage to the home/business structure is required, and no additional circuit breaker space or circuit breaker is needed to be installed in the panel, the QMC device 55 and can be direct-shipped to a customer for customer-qualified installation or installation by a professional.

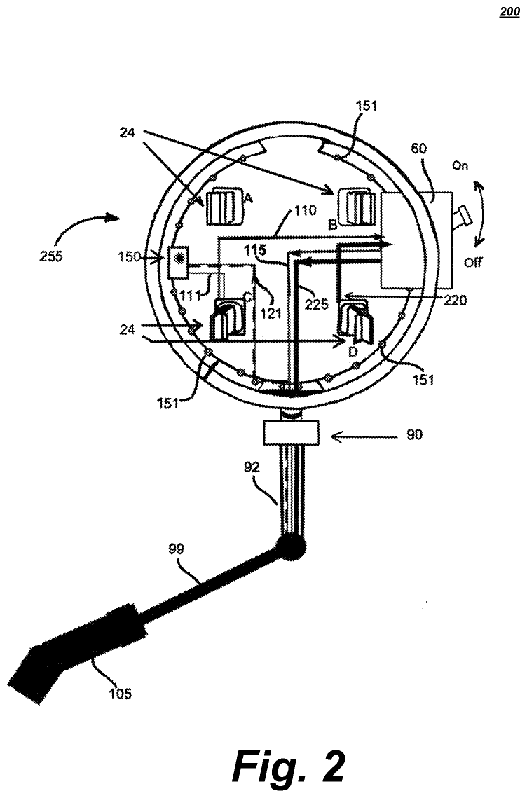

FIG. 2 is an internal wiring connection layout 200 for an exemplary QMC device 255. contact elements 24 (mirroring elements 80 in FIG. 2) are labeled as contacts A, B, (representing the utility side) C, and D (representing the metered side), which both connect to the supply panel load center (not shown) and represent the respective electrical voltages/currents taps. In this example, contact C and can provide 120V and is fed via line 110 into breaker 60. Output of the 120V from the breaker 60 is indicated by line 115 which leads into the coupler 90 into charging line 99. Similarly, for 240V, contact D's 120V is tapped and fed via line 220 into the breaker 60, joined with line 110 to add up to 240V and routed via line 115 to the charging line 99.

In this example, it is understood that any electricity tapped by a charger through contacts C & D would be reflected in the meter (not shown). Also, any electricity tapped by a charger through contacts A & B would not be metered. Contacts A & B are unused in this example, but may be also tapped according to the voltage/current output desired. Thus, multiple voltages can be provided to the charging line 99. Note: contacts A & B would not determine the voltage, the voltage would be determined by incoming utility supply.

A cut-away view of an optional conduit 92 is shown between the coupler 90 and charging line 99. At the end of the charging line 99 is the appropriate charger plug for the electrical vehicle being charged. Around a circumference of the exemplary QMC device 255, a standardized commercially used utility locking ring can be used or there can be an optional locking or attachment mechanism/controller 150 which energizes one or more locking points 151 disposed about the QMC device 255. For example, a magnetic or electric triggered lock or ring can be utilized. In operation, when the exemplary QMC device 255 is energized, the attachment mechanism/controller 150's “locking” prevents unauthorized opening of the QMC device 255. This provides a safety mechanism in addition to the circuit breaker 60. Energy for the attachment controller 150 can be obtained from tapping contact C's 120V, for example. Ground can be connected to the attachment controller 150 and fed via line 121 into the charging line 99. QMC device 255 may be constructed of metal and therefore grounded or constructed of plastic/polymer and conductor grounded through panel/load center.

In a simpler embodiment, the “locking” of the QMC device 255 can be achieved with a tightenable sleeve or via threaded connections, snap in, etc. In a prototype, the QMC device was designed with dimensions approximately 7 inches in diameter and 4.5 inches deep. Of course, as stated above, different dimensions and shapes may be used, is so desired.

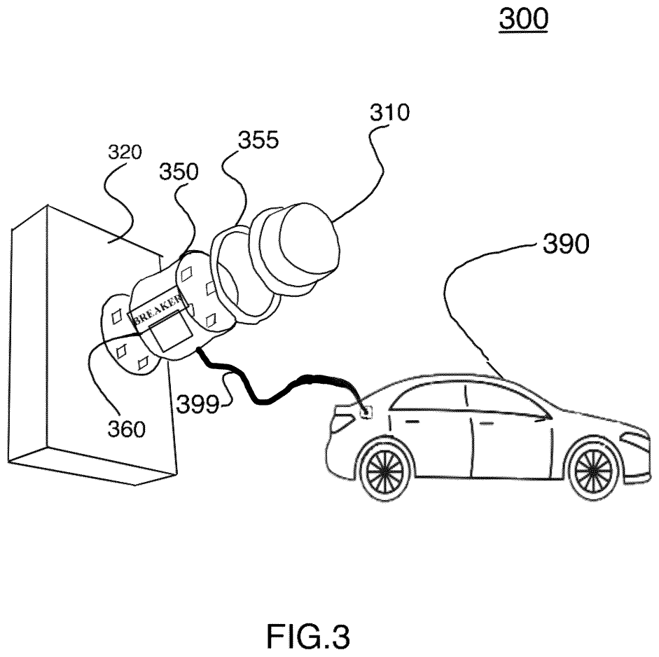

FIG. 3 is an exploded view of an exemplary QMC device 350 using a screw-tightened sleeve 355 to join the meter 310. The QMC device 350 is connected to the panel 320 via breaker 360 which provides power via the QMC device 350 into charging line 399 to ultimately charge electric vehicle 390.

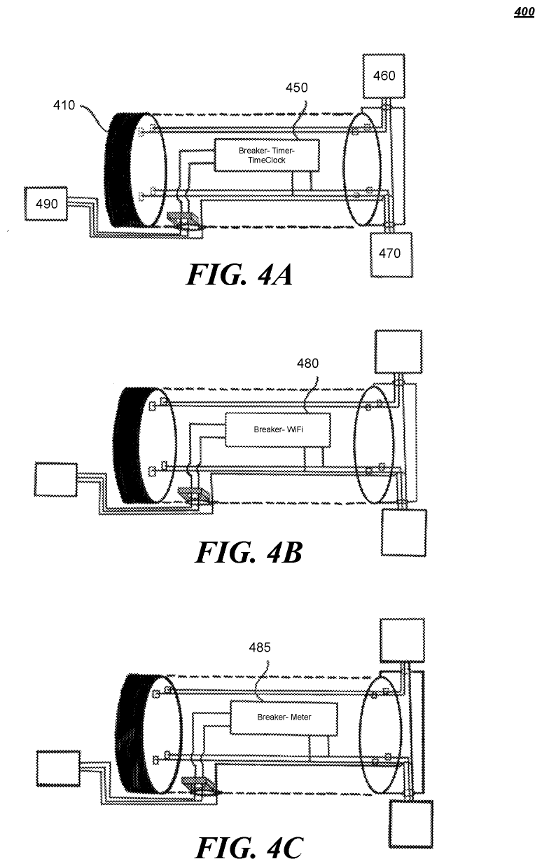

FIGS. 4A-C are block diagram illustrations of alternative exemplary embodiments. FIG. 4A is a wiring diagram displaying a Breaker-Timer-TimeClock 450 within the QMC device, so as to regulate/allow charging to electric vehicle 490 at certain times. 460 represents the electric utility supply and 470 represents the load to the electrical panel. Of course, the Timer/TimeClock portion may be separate as well as separately located from the breaker portion. FIG. 4B displays a Breaker-wireless communication capability 480 internal to the QMC device to provide separate logging of consumed charger energy. Of course, the Timer/TimeClock portion may be separate as well as separately located from the breaker portion. Alternatively, a a breaker with “analog” KWH meter combination 485 may be devised (shown here are joined to the breaker portion, but may be separate) or may be affixed to the QMC device for independent charge logging. Other possible devices and/or systems may be implemented within the “inner” portion 450, 480, 485, for example, an CPU or automatic device could provide automatic transfer of power to allow remote switching of the breakers, if so desired. Moreover, a surge protection circuit may be implemented, whereby transients entering the panel can be filtered to avoid damage to house's devices. Further, a Ground and Arc Fault Protection circuit may be implemented, providing system wide, whole house/commercial/industrial facility protection.

In alternative embodiments, the exact positioning of the circuit breaker and/or charger connection may be altered, according to design preference. Further, the rotational positioning of the QMC device may be adjustable so as to allow the QMC device to be rotated clockwise or counter clockwise as to allow the coupler and circuit breaker to be in the best possible location for use.

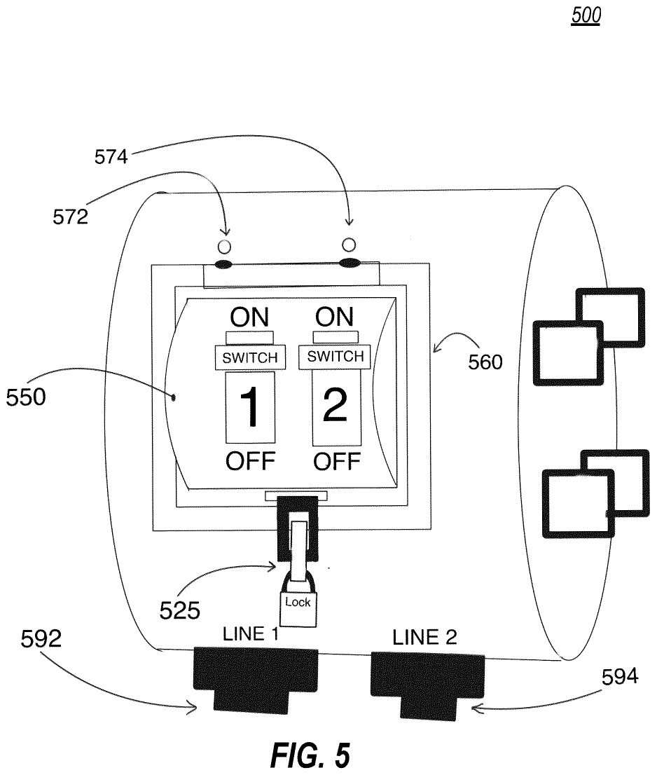

FIG. 5 is block diagram illustrating another exemplary QMC embodiment 500, and exposed panel connectors 580, wherein more than one breakers 560 are situated on the side of the QMC device 500. Each breaker 560 is connected to line-out couplers (or lines) 592, 594 providing power to/from external loads/sources (not shown). In some embodiments, the line-out couplers 592, 594 may be of a breakaway design, allowing a connected cable (not shown) to separate upon a given tension/force, either by mechanical limit, twist off, magnetic or otherwise. A cover 550 is used to provide environmental protection of the breakers 560s, wherein the cover 550 maybe transparent, if so desired, and also lockable 525 via a latch or other appropriate mechanism. Optional power/breaker status indicators (e.g., lights) may be internal to or external (as shown) to the cover 550. This embodiment illustrates a design accommodating multiple breakers-to-lines. It should be appreciated that with a multi-breaker QMC, one or more of the additional breakers may be parallel-connected to the internal power conduits, with different current/voltage values for the respective output lines, if so desired. Moreover, the one or more additional breakers may be serial-connected to a “parent” breaker, thus a tree of output lines may be controlled by a single parent breaker and downstream lines lower current-controlled with a lesser rated current breaker. As can be seen, various modifications and configurations are possible with a multi-breaker system.

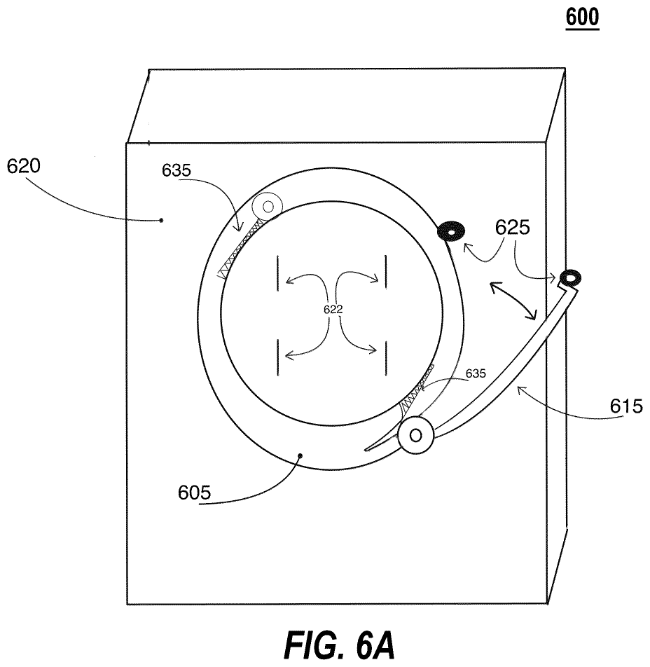

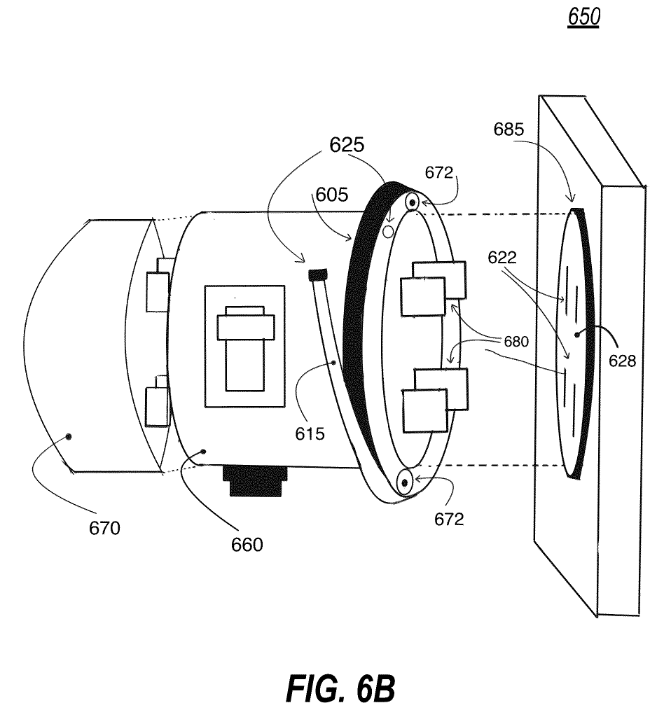

FIG. 6A is a simplified illustration 600 of a main panel 620 having a different QMC-to-Panel attachment paradigm wherein the QMC's attachment to the panel 620 is facilitated via a locking “compression” sleeve 605. The QMC (not shown) is inserted into the panel's receptacles 622 and the sleeve's 605 arm 615 is moved counterclockwise (or alternatively in other designs, CW) to tighten the sleeve 605 around a base of the QMC. If the sleeve 605 and base of the QMC are metal, then a grounding path via this approach can be obtained between the QMC and the panel 620. In some embodiments, one or more teeth or other gripping means 635 may be utilized to assist in the securing. Locking or securing the arm 615 can be achieved via overlapping rings 625 on the arm 615 and on the sleeve 605 or any other suitable location on/about the panel 620. It should be appreciated that this illustration utilizes a sleeve 605 and tightening arm 615 to provide compression about the QMC, however, other similar means wherein the sleeve 605 is not encompassing nor the arm 625 as long are envisioned. For example, the arm 615 may be replaced with a flip-clip, or engage a section of the QMC to “latch” it to the panel 620. Therefore, other possible variations are understood to be within the scope of this disclosure.

FIG. 6B is a side-view illustration showing an implementation of the attachment paradigm of FIG. 6A with a QMC 660 (and attendant meter 670) prior to attachment to the panel 620. QMC tabs 680 are inserted into the panel's receptacles 622, with the sleeve 605 fitted over the QMC's end and also over a lip 685 of the panel's receptacle face 628. The sleeve 605 may be integrally attached to the QMC 660 (e.g., a part of the QMC 660), or may be a separate element that is slipped on. One or more sleeve pivot joints 672 can assist in providing the needed compression of the sleeve 605 to attach to the lip 685. Depending on implementation design, the exemplary QMC 660 may be configured without a grounding surface contact. In some designs, the QMC 660 may be of a shape and size to attach to a ring meter socket or ringless meter socket service panels.

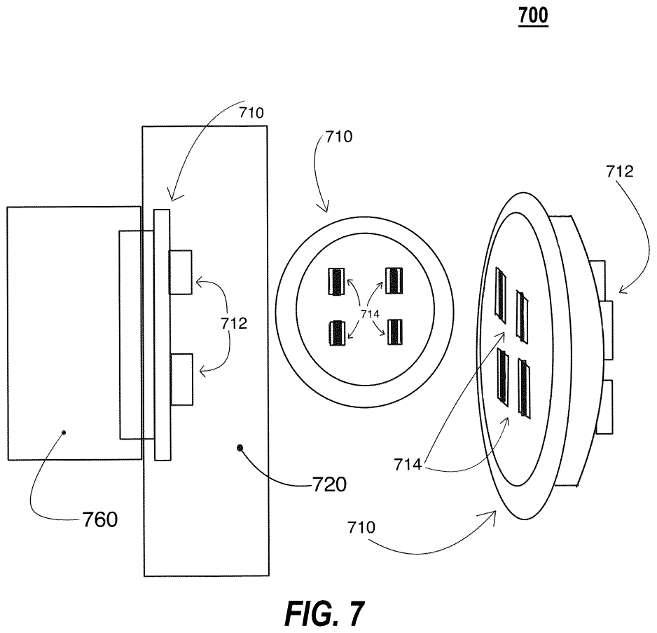

FIG. 7 is an illustration 700 of various views of another attachment mechanism showing a ringless QMC meter extension 710. Here, QMC meter extension (aka—QMC-me) 710 provides, if needed, an ability to “extend” the QMC-to-panel 720 configuration through an extension 710 having male tabs 712 and corresponding female receptacles 714. For example, if the face of the panel 720 is such that the QMC 760 is not able to “latch” onto or be secured to the panel face, then the QMC-me 710 will provide the needed structure for latching. For example, in the scenario seen in FIG. 6B, if the panel does not have a lip 685 (or its diameter is non-matching), the outer surface of the QMC-me 710 can provide the desired surface to allow attachment.

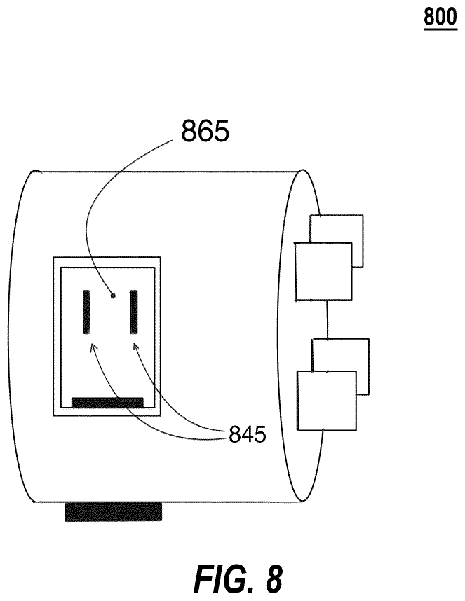

FIG. 8 is an illustration of an exemplary embodiment of a breakerless QMC 800, wherein the externally accessible breaker (not shown) is not yet installed. It is not uncommon in the electrical industry for a breaker to fail or become compromised, or a breaker is switched out for a lower/higher value. This embodiment provides an easy way to replace such a breaker without having to replace the entire QMC 800.

Of course, while FIG. 8 shows only one breakerless slot 865, the QMC 800 may have several slots, enabling multiple breakers to be installed. Over-current-protection, whether 2-pole and 3-pole circuit Breakers may be installed, wherein the system may be permit interchangeability. One or more contacts 845 for a breaker installation (and securing) are shown and are understood to be self-explanatory. This embodiment may include one or more additional features shown in other embodiments as described herein.

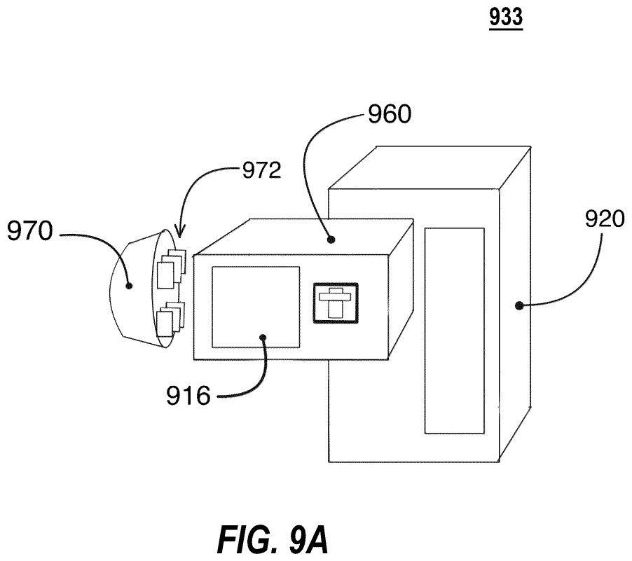

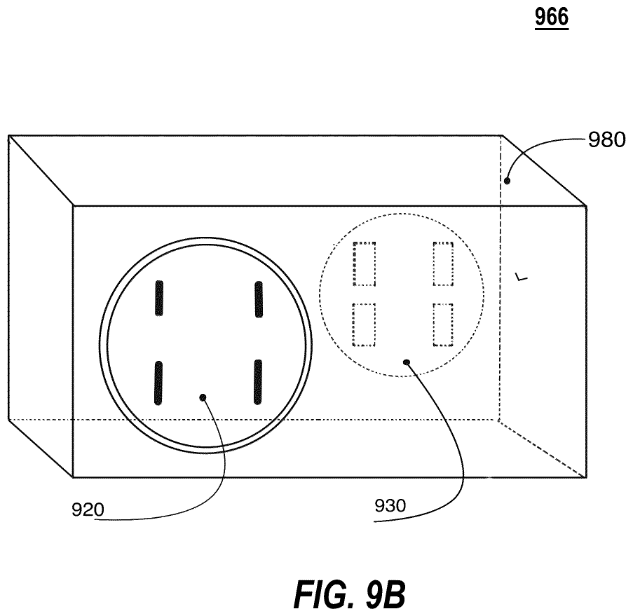

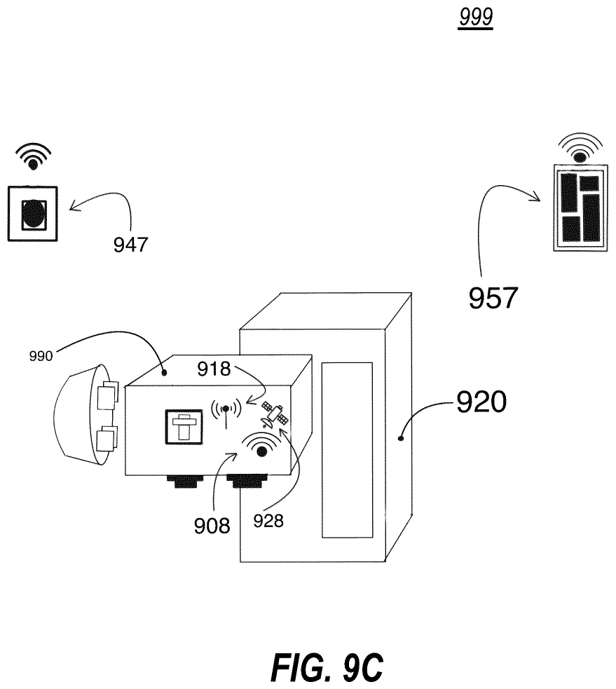

FIG. 9A is an illustration 933 of an offset meter QMC 960 prior to installation. In some circumstances it may be desirable to have meter 970 positioned offset from the panel 920. That is, the QMC 960 may be designed to reduce it length to minimize “stick out” from the panel 920. This configuration creates more room inside the QMC 960 for any number of internal selected components. In this example, the meter 970 is 90 degrees offset from the face of the panel 920. To facilitate this, an offset meter QMC 960 is contemplated that allows connection to the panel 920 and lateral positioning of the meter 970. As can be seen here, this example shows a 3-Phase 120/208V /d/ or 277/480 meter 970 arrangement due to the more than four tabs 972 on meter 970. Based on this example, it is expressly understood that other power connections, voltage choices, orientations and shapes to provide an offset meter QMC are possible. For example, one that provides a “bottom” or “top” mount meter 970, or other angles. Also, the QMC itself need not be rectangularly shaped as shown here. In this and other embodiments, due to the increased “room” inside of the QMC, additional components and circuitry 916 can be accommodated. Non-limiting examples being CPUs, automatic transfer switches/contacts, wireless systems, inverters, passive electrical devices as capacitors, inductors, chokes, etc. If sufficient capacitors are utilized, the output voltage can be increased, as well as reducing charge time. The ability to have a manual or automatic transfer switch enables back feeding to the electrical panel from either an electric vehicle's battery or from a co-generation system, such as wind, turbine, generator, solar, external battery storage system, etc. Or any combination thereof.

FIG. 9B is an illustration 966 of another offset meter QMC 980, where the meter (not shown) mount point 920 is on the left side, while the QMC 980 panel mount point 930 is on the right interior side (shown here in dashed lines). Therefore, different sides, or faces, or ends of the QMC 980 can be designed with the appropriate connections. As stated above, various other orientations, locations of contacts, shapes are understood to be within the purview of this disclosure.

FIG. 9C is an illustration 999 demonstrating an offset QMC 990 with Wi-Fi capability 908 and/or cellular capability 918 and/or satellite capability 928. Such add-ons allow the QMC 990 to provide health and status information via the wireless systems 908, 918, 928 as well as allow connection to wireless cameras 947, external devices 957 such as weather sensors, temp sensors, and any other devices. Non-limiting examples of possible provided information are: Power Logging, Voltage, Amperage, Total Harmonic Distortion, Power Factor, KVAR, KW, KWH, etc. This embodiment enables monitoring of the panel, if so desired, as well as any remotely connected device. Such monitoring can include temperature monitoring of connectors or conductors, tamper detection within the QMC 990 enclosure, etc. With wireless communication made available, the location of the power panel/QMC can be relayed to a remote system for geolocation, power logging, data management and distribution. For example, charging of a connected load (EV) may be switched off, changed by a management software or a user via a smartphone app, or based on current power costs. Or if a multi-breaker QMC is utilized, switching between breakers may be performed, as well as connecting/disconnected devices and sources/loads to the QMC. It is understood, with an offset mounting capability, an appropriate QMC can be designed to be right angle, left angle, up, down-mounted. The choice of orientation configuration and mount orientation being design dependent. Similarly, a slimmer QMC can be designed as well as a “thicker” QMC to accommodate additional electronics and components. Various non-limiting possible other examples are detailed below.

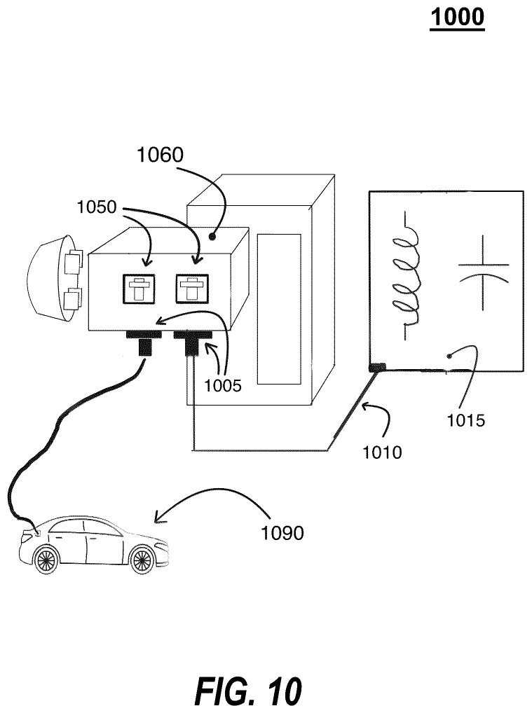

FIG. 10 is an illustration 1000 of an exemplary QMC 1060 (shown here offset for ease of illustration only) having multiple breakers 1050 coupled to multiple output lines 1005, one of which connects to an EV and the other 1010 to a reactance bank 1015. The reactance bank 1015 supplies needed inductance or capacitance to offset the reactive component of the power being consumed, for more efficient power usage. Such compensation systems are commonly seen in large industry but may be valuable for smaller scale users, given the type of loads being used today. This embodiment illustrates the ability to allow operations other than “charging” the EV 1090 to be performed via the use of a multi-line QMC 1060.

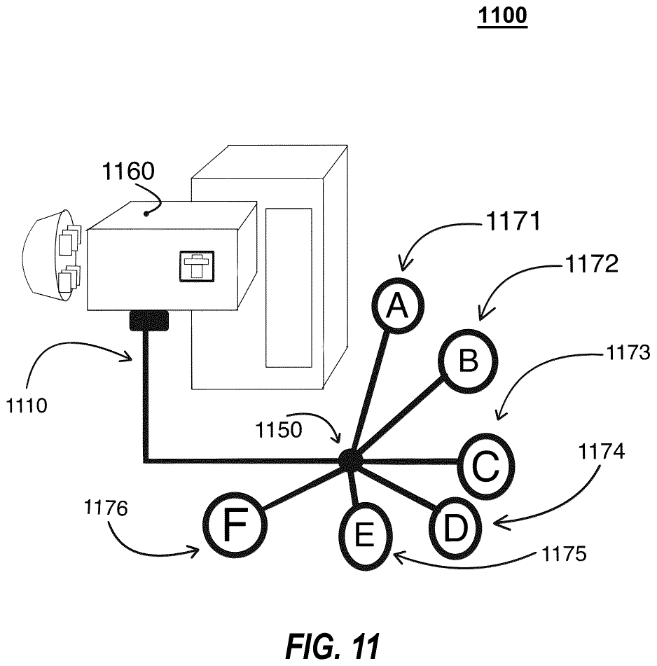

FIG. 11 is a simplified diagram 1100 illustrating the ability of a QMC 1160 (optionally offset) to be connected via line 1110 to multiple different loads and/or sources 1171-1176, with or without common junction, base, charging station 1150. While FIG. 11 shows a single breaker device, it is understood that a multiple breaker QMC can be utilized, if so desired to provide parallel paths to different loads/sources, etc. With the ability to power multiple “downstream” devices and/or receive power from multiple “upstream” devices, 1171-1176 can comprise and one or more loads/sources. Non-limiting examples are a non-local charging station, package drop receptacle, drone package drop, drone charging garage, solar panels, generators, batteries, reactance banks, inductors, capacitors, chokes, vehicles, lights, and so forth. Moreover, in various embodiments shown here, the power line or lines to the base 1150 may be underground, if so desired. Thus, some aspects of daisy-chaining, tiering and the like can be achieved.

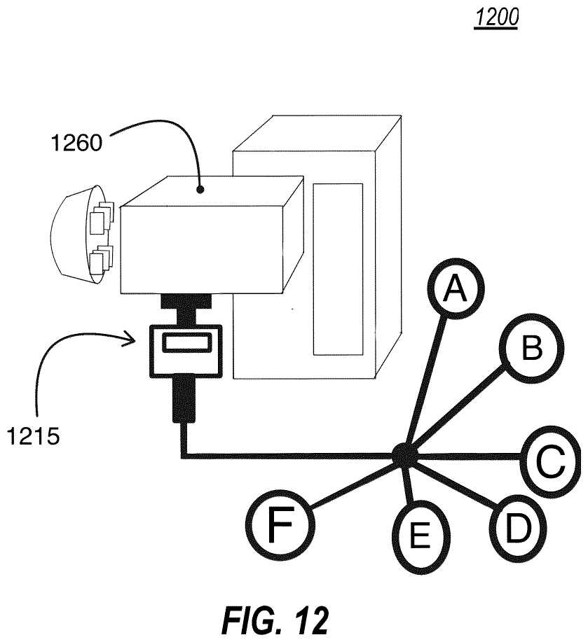

FIG. 12 is an example 1200 of a modification of the embodiment of FIG. 11, wherein a shutoff or disconnect (optionally with monitoring capabilities 1215) is positioned external to or downstream from the QMC 1260. This embodiment allows a user to control QMC-provided power remotely, when not in the immediate vicinity of the QMC 1260. As a non-limiting example, a disconnect or control system may be situated at a terminal or station where the EV (or other load/source) is located. While FIG. 12 shows a single breaker device, it is understood that a multiple breaker QMC can be utilized, if so desired to provide alternate power paths, etc.

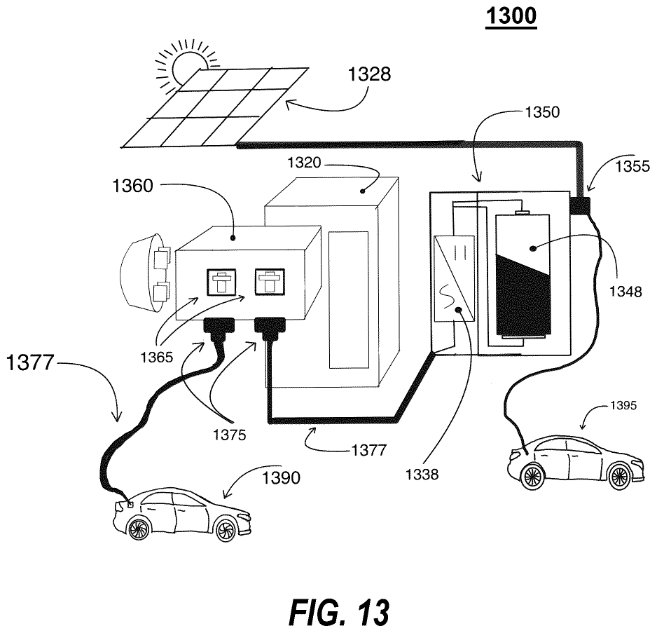

FIG. 13 is an illustration 1300 of a multi-use QMC 1360, having a plurality of breakers 1365 and attendant output/input lines 1375, connected to respective loads and sources. This example illustrates the utility of a multi-breaker/line QMC 1360, wherein one line 1377 can be used to channel power from (to) the panel 1320 to charge (discharge) an EV 1390. Secondary line 1377 can be channeled to a plurality of other power sources/loads through power center 1350. The power center 1350 can contain requisite power equipment such as high voltage DC inverter 1338 and/or battery 1348, which are connected to various sources/loads via one or more junction connections 1355. Junction 1355 allows power to come from solar array 1328 and also have that renewable power channeled to 2^{nd} vehicle 1395, if so desired. Alternatively, solar array 1328's power can be inverted via inverter 1338 and directed back to the QMC 1360 to provide power into panel 1320. Or, it may be stored in battery 1348 and or discharged at a high output DC voltage for a faster EV charge. Of course, other devices or systems, may be connected such as Wind Turbine, fuel-based Generator, sub-grid, DC super charger, etc.

The various interchanges and connections for moving power between different sources and loads, storing power, altering power, etc. are well within the ability of one of ordinary skill and therefore are understood to be self-explanatory in view of the embodiment shown here. For example, more than two breakers or the breakers may have different voltages (one being 110V, the other 240V), other types of loads/sources, etc. As seen in the embodiments of FIGS. 11 and 12, many other downstream connections may be made (star, series, parallel, etc.) and therefore various modifications to this embodiment are understood to be within the scope of this disclosure. Of course, the exemplary QMC 1360 need not be offset or of the shape shown.

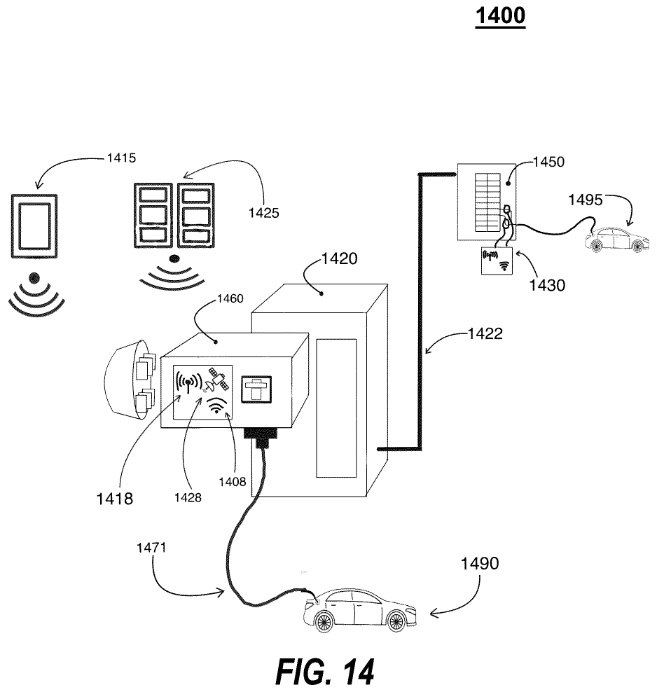

FIG. 14 is an illustration 1400 having a combination of features of various embodiments. Here, Wi-Fi 1408 and/or cellular 1418 and/or satellite 1428 capabilities are built into or “connected” to QMC 1460, with one or more input/output lines 1471 connected to an EV or source 1490. By virtue of the wireless communication ability of the QMC 1460, control and/or monitoring of a remote non-QMC “station” can be accomplished. For example, remotely located station (sub-panel) 1450 being connected 1422 to main panel 1420 may have remote EM systems 1430 communicating with QMC 1460's EM systems (1408, 1418, 1428). This remote station 1450 may be monitored by QMC 1460 and power input/output to/from remote EV 1495 can be processed or forwarded by QMC 1460, for example sent to a user's smartphone 1415 (e.g., EV 1495 is fully charged, as sub-panel 1450 is no longer drawing power, etc.), a server 1425, and so forth. Thus, someone “local” to the QMC 1460 may obtain the remote information, either by direct communication or processed by via server 1425. Further, while power is provided from the QMC 1460 to the remote station 1450 (powering a connected device(s)), it is possible for QMC 1460 to shut power off in the remote station 1450 (or to a connected device(s)) based on information received from various Wi-Fi/cellular/satellite interactions. For example, a remote EM system 1430 may indicate to QMC 1460's Wi-Fi /ellular/satellite systems (1408, 1418, 1428) that a sub-panel connected device no longer needs charging. And QMC 1460 may act accordingly. Additionally, while the above illustration shows the remote EM system 1430 as a QMC-related system, the remote EM system 1430 may operate as a Wi-Fi booster or Cell repeating station or satellite link, having no direct relation to the main QMC 1460, if so desired.

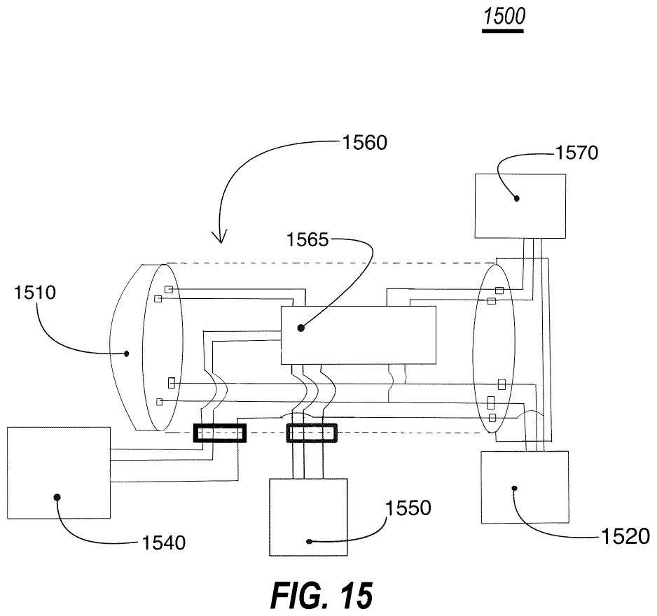

FIG. 15 is a schematic illustration 1500 of a single-phase, 2-breaker QMC 1560, showing one set of possible connections to facilitate powering of first load 1540 and second load 1550. Meter 1510 is coupled to one side of QMC 1560 and the opposite side is coupled to a service panel bringing in line power 1520 to service the home (building, factory, etc.) 1570. Typically installation locations are at a service area or service entrance, where electrical power is connected to the location. Breakers, circuitry, add-ons, etc. are represented as 1565. Of course, one or more of loads 1540, 1550 may be sources and more than two breakers may be implemented by adding additional connections in like manner.

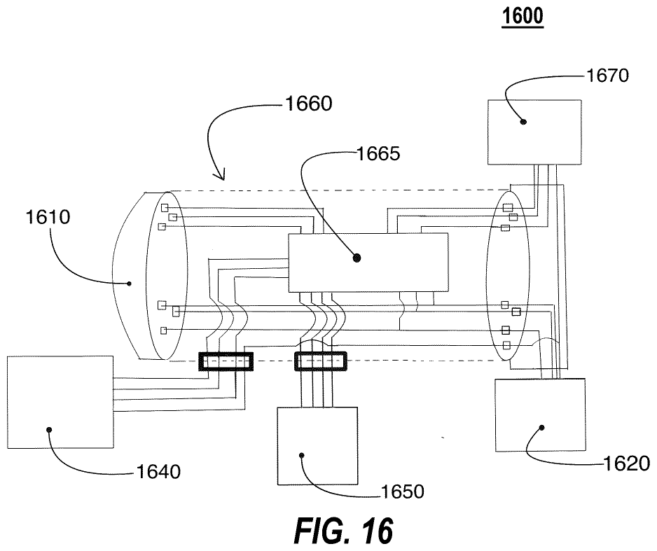

FIG. 16 is a schematic illustration 1600 of a three-phase, 2-breaker QMC 1660, showing one set of possible connections to facilitate powering of first load 1640 and second load 1650. Meter 1610 is coupled to one side of QMC 1660 and the opposite side is coupled to a service panel bringing in line power 1620 to service the home (building, factory, etc.) 1670. Breakers, circuitry, add-ons, etc. are represented as 1665. Of course, one or more of loads 1640, 1650 may be sources and more than two breakers may be implemented by adding additional connections in like manner.

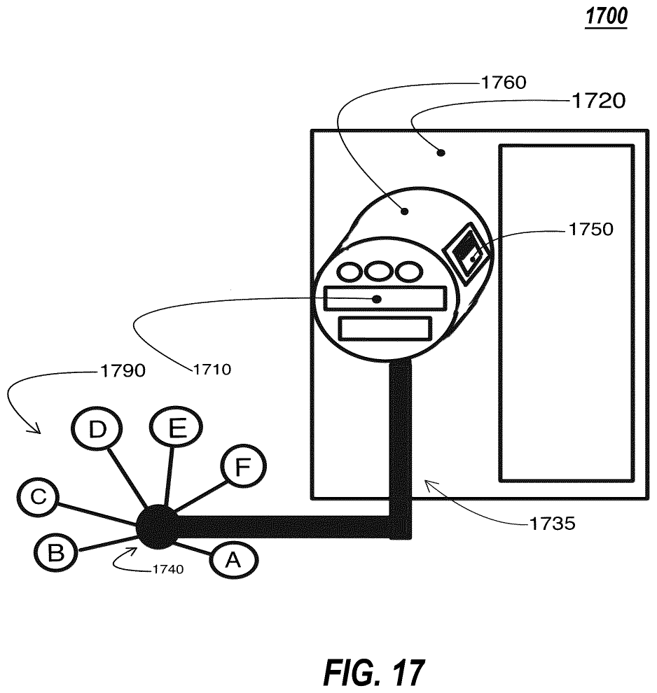

FIG. 17 is an illustration 1700 of an all-in-one QMC 1760, with a built-in meter 1710 installed onto a panel 1720. This example envisions an embodiment where the QMC and the electric utility meter are integrally designed as a single unit. The externally accessible switch (breaker) 1750 is shown in this embodiment with device-connecting cable 1735 from the QMC body that facilitates power to/from a remote station 1740 which can act as a hub or connection point for various other devices 1790 (A-F). Modifications to this all-in-one embodiment can be made according to the different designs and configurations described in the prior embodiments.

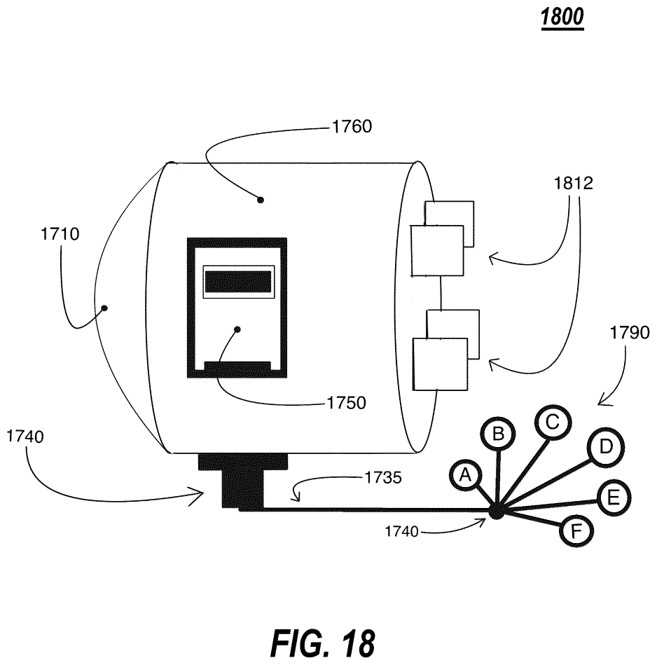

FIG. 18 is side view illustration 1800 of the all-in-one QMC 1760 of FIG. 17 separate from a panel (not shown). This illustration serves to show the exposed tabs 1812 which are used to electrically (and optionally mechanically) connect the all-in-one QMC 1760 to the panel. Connection modifications to this embodiment can be made according to the different designs and configurations described in the prior embodiments.

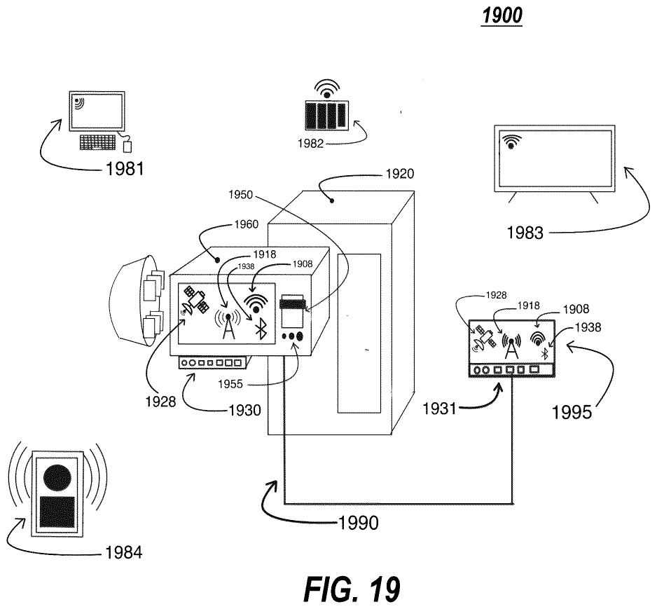

FIG. 19 is an illustration 1900 of an exemplary QMC 1960 (shown here offset for ease of illustration only) and without optional EV connection(s) but is understood that at least one EV connection can be incorporated, if so desired. QMC 1960 is shown in this non-limiting example with a single breaker 1950 and multiple indicator lights 1955, as attached to electrical panel 1920. At least one weatherproof wired data connection jack 1930 is shown as part of the QMC 1960 including but not limited to Fiber optics, RG6, CAT 5 connectors and cables, etc. This feature enables local Telecomm companies hard-wire connection capabilities for residential, commercial and community provider subscription access, through the QMC 1960, noting wireless capabilities can also be resident in the system, as described below. Therefore, in addition to providing an external power connection, the exemplary QMC 1960 facilitates external hard “communication” connections 1930. It is understood that while the jack 1930 is shown exterior the QMC 1960, it is possible to have the jack 1930 inside the QMC's housing and protected from environmental exposure. While the exemplary embodiments here describe the Telecomm companies as subscription-based, is it understood a non-subscription format is possible, wherein data of the user's choice is consumed without need for financial commitment. As a non-limiting example, various sites provide real-time weather. Or traffic updates, and so forth.

The exemplary QMC 1960 shows capabilities of at least one Wi-Fi 1908, cellular 1918, satellite 1928, Bluetooth® (The Bluetooth® word mark and logos are registered trademarks owned by Bluetooth SIG, Inc.) 1938 wireless antenna receivers/ransmitters for access to residential, commercial and community services that a Telecomm company can provide either wirelessly or through wired data connection jack port 1930. As a non-limiting example of one possible mode of use, a conduit/cable line out 1990 can be linked to a remote communication base station hub 1995 also having a data connection jack port 1931. The base station hub 1995 can also have at least one Wi-Fi 1908, cellular 1918, satellite 1928, Bluetooth® 1938 wireless antenna receiver/transmitters communications to facilitate the desired subscription services being accessible, if so designed, by QMC 1960. Alternatively, the base station's wireless communications maybe to directed to/from a non-similar system/satellite/Wi-Fi, etc. to that of the QMC's. Port for hard line 1990 at the QMC 1960 is obscured from view but can be a separate port or be part of the wired data connection jack port 1930. To a person skilled in the art, it is understood QMC 1960 and remotely located base station hub 1995 have capabilities to boost, receive and broadcast multiple signals (1908, 1918, 1928, 1938) throughout a residence, commercial facility and or neighborhood/community to various perspective wireless smart devices including but not limited to computers 1981, routers 1982, televisions 1983, extenders 1984, etc. By way of extension, the same capabilities can be afforded to smart phones, smart sensors, cameras, vehicles, automobiles, doorbells, light switches etc. In view of the above, the exemplary QMC 1960 can operate as a telecommunications gateway, if so desired. Additionally, in some embodiments, it may be desirable to have the QMC operate solely as a telecommunications gateway rather than as an over-current protection device. Thus, in these embodiments, breaker 1950 may be bypassed or rendered inoperable. For example, breaker 1950 can be replaced with a data reset button.

Conversely, base station 1995 may operate as an ‘input” whereas base station 1995 can be a satellite “dish” to the QMC 1960, or a neighborhood, building fiber-to-wi-fi drop, cable-box drop, etc. wherein base station 1995 provides the desired communication gateway to QMC 1960. It is understood that QMC 1960 could have multiple telecomm companies connected, multiple breakers and multiple data input/output lines and utilize multiple wired and wireless signals including but not limited to Fiber optics, RG6, Cat 5, cellular, satellite, Wi-Fi, Bluetooth®, etc. Therefore, other possible variations are understood to be within the scope of this disclosure.

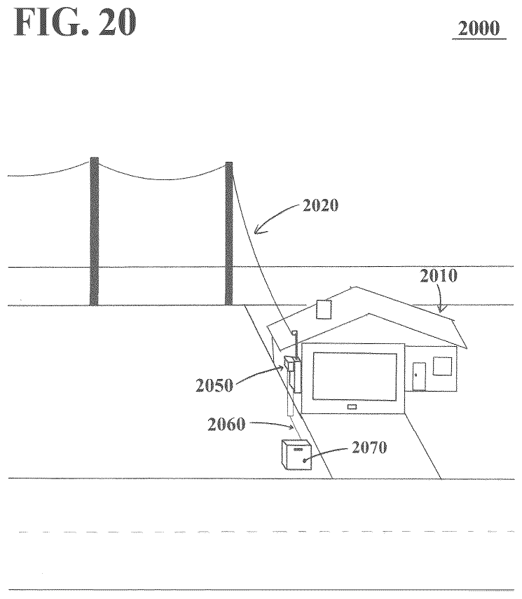

FIG. 20 is an illustration 2000 of an exemplary QMC 2050 attached to a home 2010 and powering a drop box 2070. Not seen in this example, is the QMC's connection to the home's power panel and also the utility revenue meter—as noted in previous embodiments. This embodiment contemplates the use of an external device, shown here as a road-side (or any other-situated location) drop box 2070 wherein power 2060 for the drop box 2070 is facilitated through the QMC 2050, being directly or indirectly connected to the house's incoming main lines 2020. The drop box 2070 can be for a package drop box, drone package delivery (and/or pickup), and also serve, in some embodiments as a drone charging station. Several other variations will be described below with the understanding that one or more other devices that are drop box in nature may be connected to the QMC 2050. The illustrated drop box 2070 is provided as a non-limiting example of an external device powered through the QMC 2050.

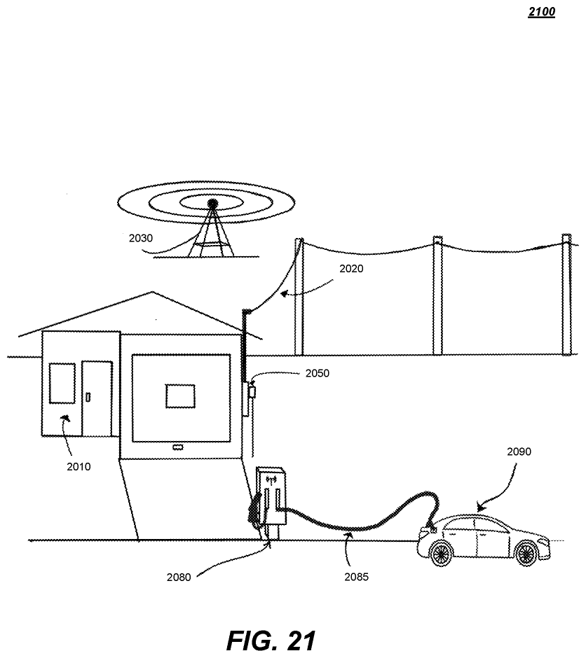

FIG. 21 is an illustration 2100 of an exemplary embodiment wherein residence 2010 is connected to QMC 2050, connected directly or indirectly to incoming mains lines 2020, which is supporting via line 2060 a charging station 2080. The charging station 2080 may have one or more available charger lines 2850 to charge a vehicle 2090. In this embodiment, the charging station 2080 is fitted with advanced electronics (not shown) to provide base-station like communication to a communication tower 2030 or the like. Such communications can be wi-fi, Bluetooth®, cellular, booster, mesh, satellite and so forth.

FIG. 22 is an illustration 2200 of an exemplary QMC 2050 coupled via power line 2060 to a multi-use charging station 2280, having in this embodiment both a charging capability and a drop box capability. The “opening” 2282 for the charger-drop box 2280 may be situated anywhere that is convenient, being shown in this FIG. as facing a road (not shown). This allows the charger-drop box 2280 to also act as a mail box, delivery receptacle and so forth. Appropriate security and electronics may be implemented in the drop box portion to allow some mode of communication to the residence 2050 and/or owner (not shown), for example to notify if a package or object has been delivered into charger-drop box 2280.

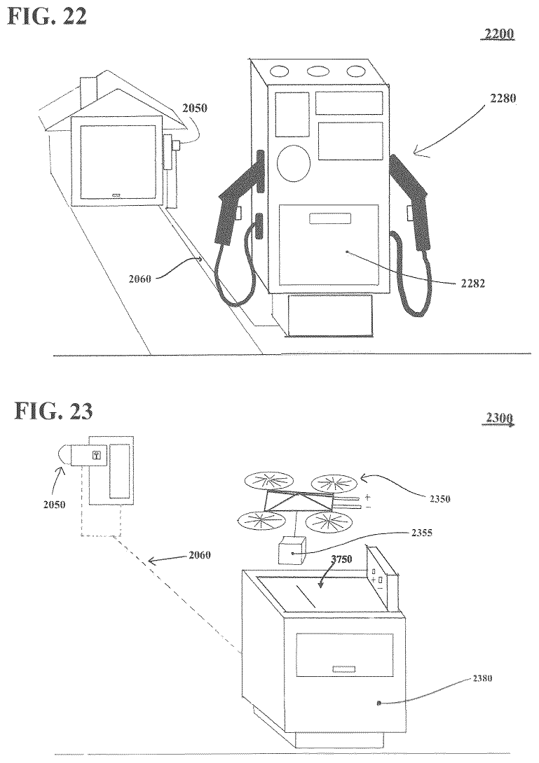

FIG. 23 is an illustration 2300 of an exemplary embodiment QMC 2050 coupled via power line 2060 to a stand-alone drone-facilitating automatic drop box 2360. This embodiment illustrates a drone 2350 delivering an item 2355 into an available access 2370 within the automatic drop box 2360. Means and mechanisms for allowing access 2370 are well known in the art, a few non-limiting examples being a mechanized swinging door, sliding, metal curtain, etc. When fitted with appropriate electronics (not shown), the automatic drop box 2360 can “open” its access 2370 upon imminent delivery and close it after delivery. Some versions of the automatic drop box 2360 can be configured to provide charging capability to a visiting drone 2350. Thus, a drone 2350 may deliver and/or pickup an item and during its commission, be recharged by the charging station 2360 for the next flight. The drone charging infrastructure may be external to the automatic drop box 2360 or it may be internal, within the access 2370.

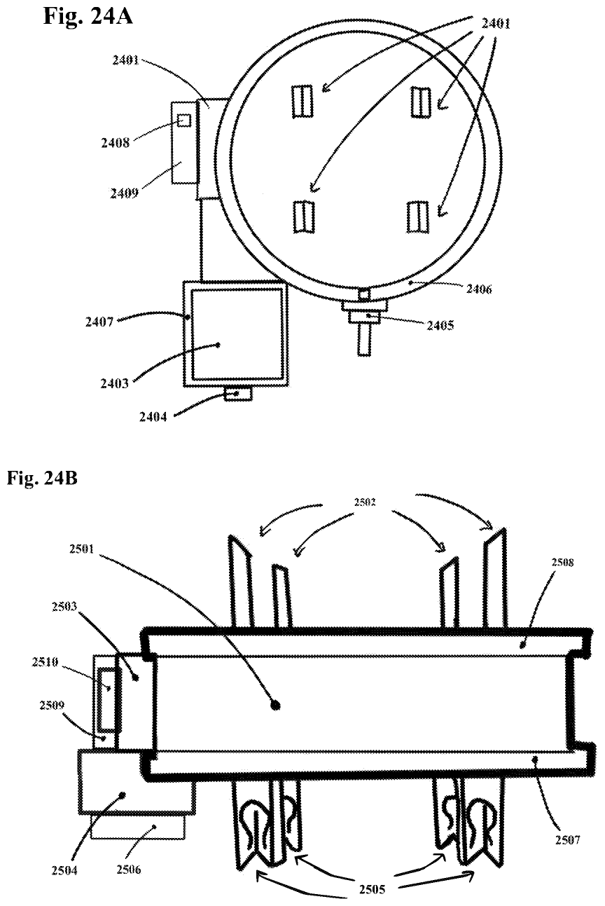

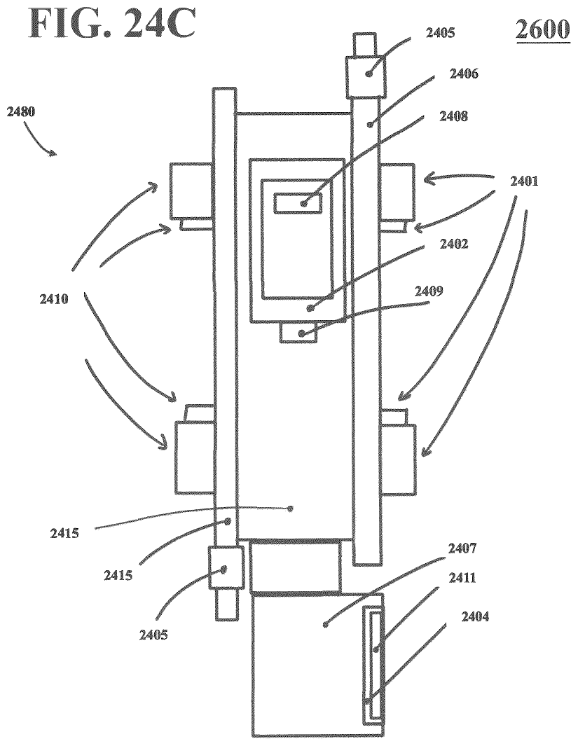

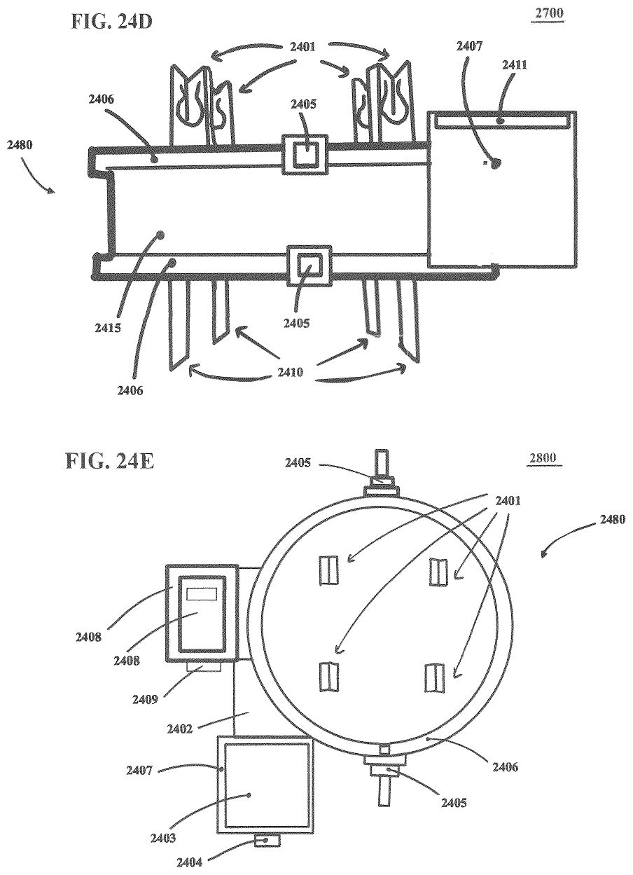

FIGS. 24A-D are different views of another exemplary QMC 2480, some views showing optional elements/locations. FIG. 24A is a front view 2400 of exemplary an QMC 2480, showing four meter-side socket jaws or terminals 2401 for coupling to a standard utility meter (not shown). Side enclosure 2402 contains pathways for overcurrent protection devices (e.g., breakers or fuses) 2408 being housed in a securable or lockable housing 2409. The lockable housing 2409 may be transparent, allowing a user to see if a breaker has tripped or not, status, etc. A waterproof high/low voltage receptacle 2403 is housed within a waterproof receptacle enclosure 2407 having securing “lock” 2404 or cap to restrict access. The waterproof high/low voltage receptacle 2403 provides connection via the overcurrent protection devices 2408 to the main power, thus allowing an external (power tapping and/or power inputting) connection to be made. Attachment means 2406 (shown here as a ring) provides additional securement of a utility meter (not shown) to the exemplary QMC 2480. The attachment means 2406 can have a “tightening” and/or locking feature 2405 that fixes the attachment means 2406 as well as prevent unauthorized opening. Tags, markers (not shown) may be affixed to the locking feature 2405, as desired. In some embodiments, the attachment means 2406 may have locking feature 2405 on its side and thereby “latch” onto a section of the panel (not shown) or the meter (not shown). Thus, the desired location of the attachment means 2406 may vary according to design preference.

FIG. 24B is a top view 2500 of the exemplary QMC 2480 of FIG. 24A with a slight modification. Shown in this view are the panel side stabs 2410 and the opposing jaws 2401 for coupling to a standard utility meter (not shown). Main body 2415, having one or more attachment ring(s) 2406, bridges the two sides, wherein side enclosure 2402 houses overcurrent protection devices (e.g., breakers or fuses) 2408. Adjacent to side enclosure 2402 is securable/locking housing 2409, leading to waterproof receptacle enclosure 2407 housing the high/low voltage receptacle 2403.

FIG. 24C is a side view 2600 of the exemplary QMC 2480 of FIG. 24A with a slight variation in the location of locking elements. For example, side enclosure 2402 has its lockable/securing element 2409 on a bottom of the side enclosure 2402. Also, waterproof receptacle enclosure 2407 housing the high/low voltage junction attachment enclosure and or receptacle (not visible) contains a “front” access cover 2411 which is secured by a lock 2404 on the face or by a side of the cover 2411. Of course, means and locations for locking, controlling access can be facilitated in different ways, according to one of skill in the art. From this FIG. view, two attachment ring(s) 2406 are visible, on each side of the main body 2415, with their attendant “tightening” and/or locking features 2405 on opposite sides of the attachment ring(s) 2406.

FIG. 24D is a bottom view 2700 of the exemplary QMC 2480 of FIG. 24C but with the attachment ring(s) 2406 tightening features 2405 on the same sides. This FIG. serves to show various orientations and combinations which may be possible. The remaining reference numbers shown in this FIG. correspond to the like elements described in FIG. 24C and are understood to be duplicative and thus are self-explanatory.

FIG. 24E is a front view 2800 of the exemplary QMC 2480 of FIG. 24C but with waterproof junction attachment enclosure and or receptacle enclosure 2407 having its securing “lock” 2404 or cap disposed on the bottom and the tightening” and/or locking features 2405 on the attachment ring(s) 2406 configured to allow a tag or label to positioned therein. The tagging provides a means to demonstrate that the device has not be tampered with and also may facilitate any maintenance, or other labeling to the device. The remaining reference numbers shown in this FIG. correspond to the like elements described in FIG. 24C and are understood to be duplicative and are thus self-explanatory.

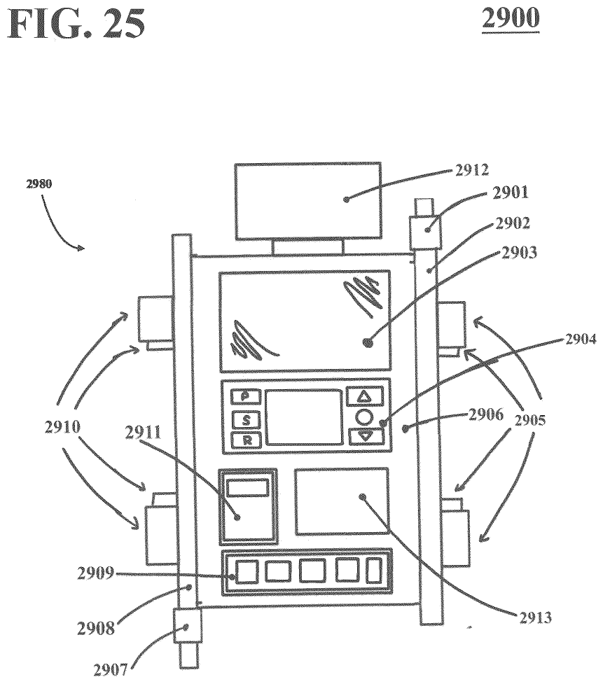

FIG. 25 is a side view 2900 of an exemplary QMC 2980 displaying the panel side stabs 2910 and the opposing jaws 2905 for coupling to a standard utility meter (not shown), is equipped with a communication data booster/repeater with transmitting and/or receiving capabilities embedded therein. Power to run the communication system can be tapped from the QMC internal wiring. The circuitry of the data booster/repeater itself are understood to be within the QMC 2980, wherein external systems/elements are shown in this FIG. For example, antenna 2912, display 2903, control buttons/keys 2904, data comm connections/ports 2909, and optional near field sensor 2913 are shown, noting some elements may combined or further segregated according to design preference. The data ports 2909 can be of any interface type, such as USB, RS-485, RJ45, CAN bus, optical, or proprietary communication interfaces.

In some embodiments, the antenna 2912 may be of an optical nature, and removable or replaceable. Such communication capability whether wireless or via the data ports 2909, provide data transmission for control, diagnostics, or system monitoring, firmware updates, boosting, data logging, remote control, etc. In other embodiments, the display 2903 may be touch sensitive, thus eliminating the need for physical buttons 2904. Attachment ring(s) 2902, 2908 with attendant securing/locking feature 2901, 2907 border the sides of the exemplary QMC 2980. Overcurrent protection devices (e.g., breakers or fuses) or in some embodiments, a disconnect switch 2911 can be disposed in the same side as the display 2903 or buttons 2904. Of course, the communication system may contain one or more communications capabilities current in the art, non-limiting examples being Cellular, Satellite, Mesh, Wi-fi, Bluetooth®, Near Field, and so forth.

Due to the ability to perform communications, either wirelessly or even wired (via the power line(s)) the exemplary QMC 2980 may communicate directly or indirectly to systems that being powered by the QMC 2980 or supporting systems. For example, server running software may communicate to the QMC 2980 and also communicate to any device being powered by/coupled to the QMC 2980. As noted in prior embodiments, an EV being charged may have wireless/satellite capabilities, wherein communication from the EV can be routed to the QMC 2980 via the QMC's communication systems. Similarly, the EV may communicate to the QMC 2980 and use the QMC's communication system to forward the EV data to a QMC-linked server, etc. Additional aspects are evident from the previous FIGS. With such capabilities, various management and control of connected and related systems can be operated, wherein the QMC 2980 can regulate power to various connected systems, in accordance with local or remote management/control software. It therefore is possible to utilize the exemplary QMC as a means for payment as well as inventory management, as services (power, detection of a connected device, etc.) are handled via the QMC. It is understood that in various upstream and downstream utilization paradigms, the QMC may serve in a more generic capacity as an intermediary charging interface (ICI), this nomenclature being interchangeable.

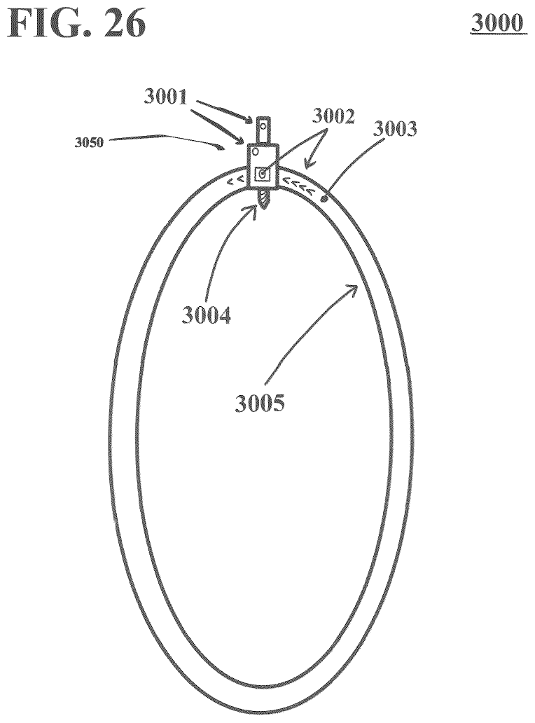

FIG. 26 is an illustration 3000 showing an attachment ring 3005 with various features of a securing/locking mechanism 3050. Understanding that in some embodiments of the attachment ring 3005, the ring 3005 may be larger than the QMC's diameter and therefore a ratcheting or like is performed to shorten the ring 3005 to “fit,” whereas grooves or other mechanical features can be on the ring 3005 and locking mechanism 3050 (shown here as 3002). Such components can be mechanically restrained to prevent displacement or tension using one-hole straps, two-hole straps, magnetic anchors, screws, nails, adhesive bonding, or equivalent securing means. Fitting is understood to be desirable as this serves to “seal” the QMC to the panel/meter and prevents the entry of water or other environmental elements. The fitting or sealing can be further enhanced with raceways, flexible conduits, seal-tight conduits, etc. Of course, fitting/sealing can be accomplished by numerous other ways, non-limiting examples being clamps, bolts, registration holes, etc. Both the mid-part and upper parts (3001) of the locking mechanism 3050 may be designed to accommodate tamper resistant tag(s), labels, etc. The bottom part 3004 of the locking mechanism 3050 can serve as part of the fitting/tightening structure but also as a “ground” conducting point, for ground protection. That is, a separate (not shown) line to ground may be attached to the bottom part 3004, if so desired. The terms bottom and top are understood to be interchangeable, as the attachment ring 3005 may be inverted from what is shown, as well as the locking mechanism 3050. The attachment ring 3005 (and locking mechanism 3050) may be made of conductive material (or not, depending on design preference) and additionally may be painted with a non-conductive paint, rubber, latex, etc. wherein bottom part 3004 of locking mechanism 3050 can be not painted to provide an exposed conductive (connected to a ground wire) section of the joint assembly.

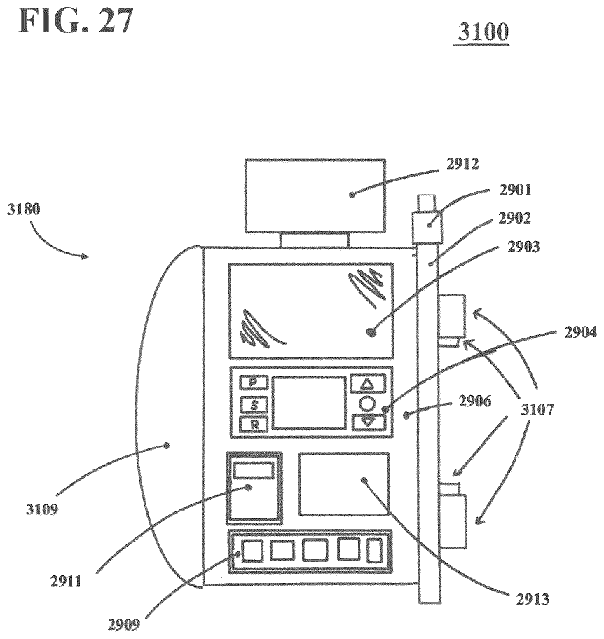

FIG. 27 is a side view 3100 of an “all-in-one” exemplary QMC 3180 showing exposed panel side stabs 3107 and with a pre-attached (or integrated) utility meter 3109 and with a communication data booster/repeater with transmitting and/or receiving capabilities embedded therein. This embodiment has the equivalent of the utility company's provided meter, already affixed to the QMC 3180. Because the meter 3109 is provided, an attachment ring on the meter side is not necessary. Of course, this assumes the utility meter 3109 is fixed to the QMC 3180, perhaps permanently or in a manner that does not rely on an attachment ring. This embodiment serves as a complete replacement of the original meter while providing meter and QMC features. In some embodiments, the pre-attached meter 3109 may have metering that is independent from the panel side draw, thus independently tracking usage from the QMC's external connection (e.g., EV charger line). Elements 2901, 2902, 2903, 2904, 2906, 2909, 2911, 2912, 2913 are duplicative of the elements described in FIG. 25 and are thus self-explanatory.

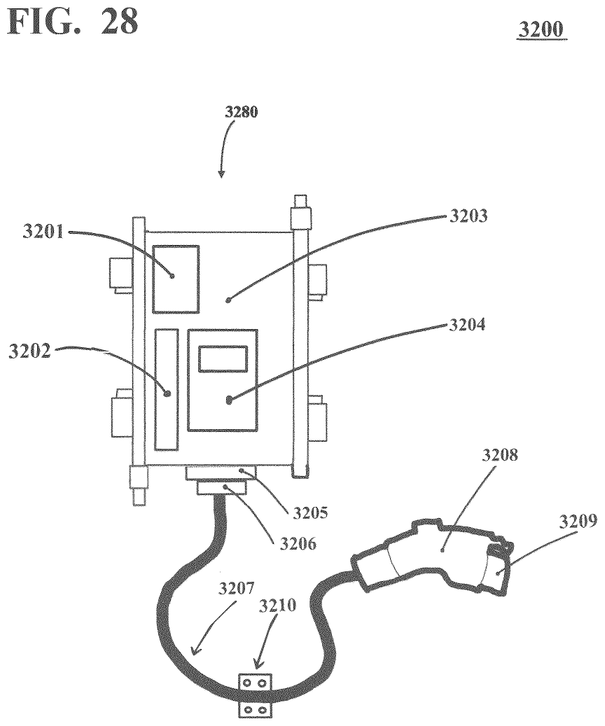

FIG. 28 is a side view 3200 of an exemplary QMC 3280 with an attached corded charger 3208. Within or about the body 3203 of the QMC 3280 is a Control Board 3201 with Current sensors to close/limit circuit current to 20/30/40/50/etc. amps to the EV (not shown) which is within the capacity of a standard household service panel (not shown). The Control Board 3201 may contain real-time current-sensing elements, solid-state or electromechanical switching relays and or devices, wherein the control system is configured to monitor load capacity of an electrical service panel and dynamically limit current flow to an electric vehicle charging output based on the available capacity of the service panel, thereby maintaining safe operation and optimizing available electrical capacity. The Control Board 3210 capabilities for limiting and or throttling current through the exemplary QMC 3280 can be based on panel size and available panel capacity at a given moment. In some embodiments, the control board 3201 adjusts current limits in response to local sensing, remote control signals, or a combination thereof.

With or in addition to the first Control Board 3201, a secondary Control Board with current limiting sensors 3202 for 20/30/40/50/60/70/80/90/100 Amps is shown within or about the QMC 3280. Depending on the service panel's capability, the implemented Control Board 3201 and current sensors/limiters may have different current limitations.

An overcurrent protection device(s) (e.g., one or more breakers or fuses) 3204 is situated on the QMC 3280, to enabling a user to reset the QMC 3280 upon a current overload response. In some embodiments, a surge protector may be part of the overcurrent protection device(s) 3204 or may be part of one of the Control Boards 3201, 3202.

Charger cable 3207 is coupled to the QMC 3280 via one or more securing couplers 3205, 3206, which may be of a quick release form, if so desired. The quick release capability prevents damage to the QMC 3280 if the cable 3207 is pulled too taut. Additionally, a cable support, or strapping and securing as per National and local Electric codes 3210 can be provided to “hold” the cable 3207 and relieve tension off the QMC 3280. Cable 3207 is terminated with the appropriate EV charger “nozzle” 3208 and EV mating connection configuration 3209.

It is understood that in some embodiments, remote control of the Control Board 3201 may be facilitated, via communication means, as described herein, enabling the opening and closing of the flow of current from the utility side to house and to the QMC 3280. It is expressly understood that due to the capability of controlling the current distributed by the exemplary QMC 3280, via use of the Control Board 3201 (and built-in communication capabilities) that aspects of device load control, authorization, dispatch, power flow changes, distribution to different endpoints, and so forth can be accomplished. Thus, software implementation of load distribution, asset management, resource utilization, etc., being powered or charged via the exemplary QMC 3280 may be leveraged through a server connection, in communication to one or more QMCs. Accordingly, various connected devices, their charge consumption, time of use, type of device, and so forth may be integrated, or controlled to a certain degree via judicious management via one or more QMCs. As one non-limiting example, a platform server running resource management software/programs can be in communication to one or more QMCs having power-connected devices (e.g., electric vehicle, etc.) wherein their power delivery is selectively controlled. In such embodiments, the execution of software-based management functions results in a physical change in electrical power delivery at the QMC 3280 through actuation of the controllable power circuitry.

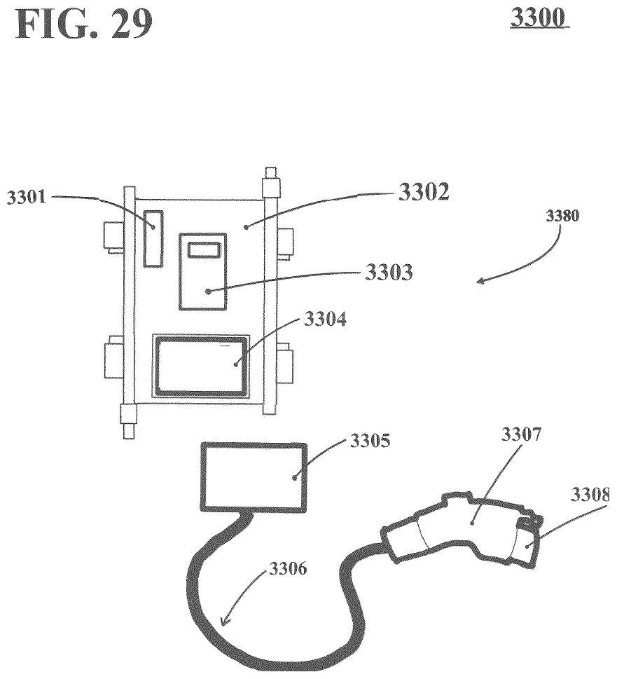

FIG. 29 is a side view 3300 of an exemplary QMC 3380, similar to the embodiment of FIG. 28, however with a different “quick connect/disconnect” configuration and with lower voltage communication between a device or EV (not shown) and the QMC 3380. In this embodiment, the QMC 3380 does not have a high voltage a receptacle, but rather a non-contact charging-cord attachment assembly that provides quick-release or breakaway functionality without the use of exposed male-to-female conductive interfaces. The QMC-side quick connect/disconnect” assembly on the QMC 3380 is shown as element 3304, while the cable-side mating assembly 3305 is shown coupled to the charging cable 3306. Wherein the cable 3306 is terminated with the appropriate EV charger nozzle 3308 and EV mating connection configuration 3309. The low voltage communication can be facilitated thorough the charging cable 3306 having an embedded communication channel configured in accordance with recognized devices, or electric vehicle communication protocols, wherein the embedded channel enables data exchange between the QMC 3380 and the connected electric vehicle for charging controls, diagnostics, and safety verification. Control Board with Current sensors 3301 is seen within or about the body of 3302. An overcurrent protection device(s) (e.g., one or more breakers or fuses) 3304 is situated on the QMC 3380. In some embodiments, disengagement of the quick connect/disconnect assembly automatically interrupts electrical power delivery and triggers a safety or status notification.

The connect/disconnect” assembly 3304 can be operable through one or more of: electromagnetic coupling, magnetic alignment, inductive transfer, or mechanical clip-and-clasp engagement. wherein charging cable 3306 is replaceable without electrical disconnection of the primary QMC 3380. It is expressly understood the charging cable 3306 also have a capability to be retracted or extended using conventional retraction mechanisms. Non-limiting examples are a spring-biased reel, motor-driven reel, gravity-assisted reel, or powered winding. Also, it is contemplated, with the retraction mechanism, the charging cable 3306 may not be energized until a predetermined length has been extended and conversely, automatic shutoff upon a predetermined length of retraction.

It is expressly understood that charger nozzle shapes and types may vary according to manufacturer preference; and EV mating connection configurations may vary as well. Some non-limiting examples being Type 1, 2, 3, 5 Pin, 7 Pin, 9 pin, J17782, North American Charging Standard (NACS), Combined Charging System (CCS), Combo 1/2(CCS1/2 ), Supercharger, etc.

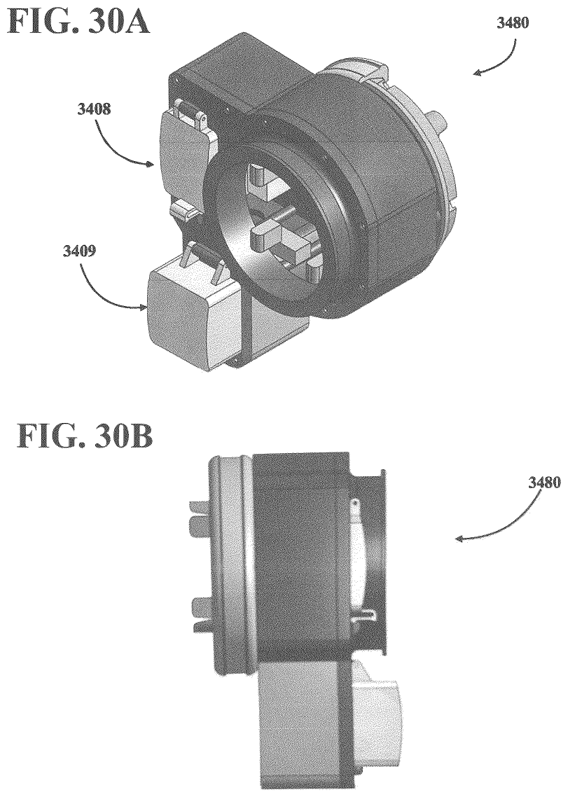

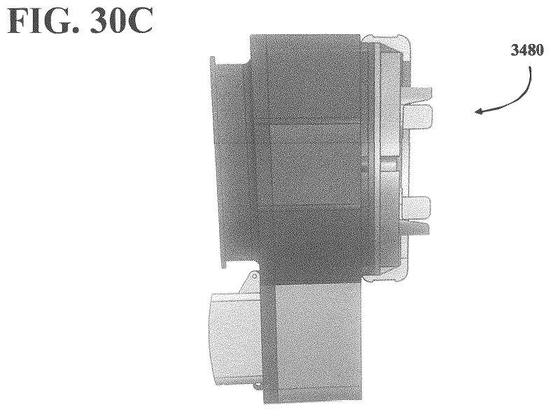

FIGS. 30A-C are different views of a 3-D rendering of an exemplary QMC 3480 and are representative of one or more simpler embodiments of the previous FIGS. Of visible note is the cover for overcurrent protection devices (e.g., breakers or fuses) 3408 and the cover for the high/low voltage receptacle 3409 (charger cable connection). Other elements seen in the FIGS. are self-explanatory in view of the prior descriptions and only shown here to demonstrate just one of many appearances that are possible.

FIG. 30A is a front perspective view of an exemplary 3-D rendered QMC 3480. Protective covers3408 for the breaker and cover 3409 the external line connection are shown.

FIG. 30B is aside view of exemplary 3-D rendered QMC 3480 and is understood to be self-explanatory.

FIG. 30C is an opposing side of exemplary 3-D rendered QMC 3480 and is understood to be self-explanatory.

While the above FIGS. show a particular form factor of one or more exemplary QMCs, it is understood those form factors are not restrictive to the final appearance of an QMC. That is, non-circular housings may be devised, as noted in the earlier FIGS.

All possible combinations of elements within the various QMC embodiments are not possible to illustrate, therefore, it is understood that one or more elements of different exemplary embodiments of the QMC may be combined, removed, adjusted into other embodiments, without departing from the spirit and scope of this disclosure. As one non-limiting example, solar power, reverse charging, and so forth may be implemented in the latter QMC embodiments, according to design preference. Additionally, several different or like devices may be connected in series and/or in parallel to the external power line(s). Therefore, the examples shown are not to be considered limiting to the breath of modifications that can be made. Thus, this and other arrangements described herein are for purposes of example only. Those skilled in the art will appreciate that other arrangements and other elements (e.g., machines, interfaces, functions, orders, and groupings of functions, etc.) can be used instead, and some elements may be omitted altogether according to the desired results. Further, many of the elements that are described are functional entities that may be implemented as discrete or distributed components or in conjunction with other components, in any suitable combination and location.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims.

What is claimed is:

1. An electrical quick meter connect device, comprising:
an environmental housing with a first face is configured with connectors to mate directly to an electrical service panel in a meter connection manner, and a second face configured with connectors to mate directly to a utility meter in an electrical service panel connection manner;
a first and second set of lines, internal to the housing, coupled to the first face to the second face;
at least one breaker switch integral to and disposed on an external side of the housing and coupled to at least one of the first and second set of lines; and
at least one external power line coupled to the at least one breaker switch and exiting the housing providing at least one of external power output and input to at an externally located device,
wherein the quick meter connect device is configured to be inserted directly between a meter and electrical service panel to provide external power connection.

2. The device of claim 1, further comprising an environmentally secure power line coupler between the at least one breaker switch and the at least one external power line, enabling the external power line to be removably coupled from the quick meter connect device.

3. The device of claim 1, further comprising at least one of a timer, clock, wireless transmitter, cellular transceiver, computer, control board, surge protector, Wi-fi, cellular repeater, satellite transceiver, Bluetooth® device, control buttons, data communication port, display, and near field sensor is coupled to at least one of the first and second set of lines.

4. The device of claim 1, further comprising at least one of a timer, clock, wireless transmitter, cellular transceiver, computer, control board, surge protector, Wi-fi, cellular repeater, satellite transceiver, Bluetooth® device, control button, data communication port, display, and near field sensor are disposed within the externally located device.

5. The device of claim 3, further comprising, a replaceable antenna module, a tamper sensor and temperature sensor, wherein at least one of control, diagnostics, system monitoring, boosting, and over-the-air firmware updates are facilitated through the replaceable or internal antenna module.

6. The device of claim 2, further comprising, a lockable weatherproof cover over the at least one breaker switch and the environmentally secure power line coupler.

7. The device of claim 1, wherein the externally located device is a charging station and a charging cable is connected to the charging station.

8. The device of claim 7, wherein the charging cable is adapted to conform to at least one of a Type 1, 2, 3, 5 Pin, 7 Pin, 9 pin, J17782, North American Charging Standard (NACS), Combined Charging System (CCS), Combo 1/2(CCS1/2 ), and Supercharger.

9. The device of claim 6, wherein the environmentally secure power line coupler is at least one of a contact and non-contact charging cord attachment assembly with at least one of a quick-release and breakaway functionality.

10. The device of claim 1, further comprising an integrated utility connected meter.

11. The device of claim 1, wherein at least one of single-phase, 3-phase power, 120V, 240V, 208V, 277V, 480V, 600V, and breaker-limited amperage is provided to the at least one external power line.

12. The device of claim 1, further comprising, at least one of a charging station for an electrical vehicle, a drop box, and a drone charger, wherein there is a low voltage line between the at least one charging station for an electrical vehicle and the electrical vehicle.

13. The device of claim 12, wherein the drop box has an access-controllable entry.

14. The device of claim 1, further comprising a control system, containing at least one of a real-time current-sensing element, a controller board, and a switching relay, wherein the control system is configured to monitor load capacity of an electrical service panel and dynamically limit current flow to the at least one external power line.

15. The device of claim 14, wherein the controller board is configured to monitor panel load and regulate current in accordance with a predetermined panel capacity allowance.

16. The device of claim 1, further comprising a quick meter connect device coupler, coupling one side of the quick meter connect device to an electrical service panel.

17. The device of claim 16, wherein the quick meter connect device coupler is at least one of a circular strap, seal tight conduit, a sealing ring, and electrical cord having at least one of a hole, a magnetic anchor, a screw, a nail, a mechanical latch, and an adhesive to secure the quick meter connect device.

18. The device of claim 16, further comprising at least one of a ground connection and a label coupled to the quick meter connect device coupler.

19. The device of claim 1, further comprising at least one of a manual and automatic transfer switch.

20. The device of claim 19, further comprising at least one of an electric car, solar panel, wind turbine, generator, battery storage, sub-panel, reactance bank, capacitors, inductors, chokes, grid, and inverter, connected to the at least one manual and automatic transfer switch.

21. The device of claim 1, further comprising a plurality of remote devices connected in at least one of series and parallel to the at least one external power line.

22. An electric vehicle charging interface device, comprising:
a meter-side electrical interface configured to couple directly to a utility revenue meter socket;
a load-side electrical interface configured to supply power to an electrical panel or electric vehicle charging equipment;
a controllable power circuit disposed between the meter-side electrical interface and the load-side electrical interface; and
a controller configured to selectively authorize, limit, or interrupt electrical power delivery through the controllable power circuit in response to at least one of a utility control signal, a load condition, or a safety condition.

23. An electric vehicle charging coordination system, comprising:
a plurality of electric vehicle charging interface devices (EVCID), each EVCID configured to control electrical power delivery to an electric vehicle, wherein at least one EVCID of the plurality of the EVCIDs is coupled directly to a utility revenue meter socket and has a controllable current interrupt switch on an outer surface;
a platform server configured to communicate with the plurality of EVIDs; and
a resource management software executed by the platform server,
wherein the resource management software is configured to at least one of receive charging requests, determine authorization conditions based on at least one of grid capacity, utility policy, and safety constraints, and selectively cause electrical power delivery to be enabled or disabled at one or more of the EVIDs.

24. A method of coordinating electric vehicle charging, comprising:
receiving, at a platform system, a request to initiate electric vehicle charging;
evaluating one or more authorization conditions associated with at least one of an electrical grid capacity, utility requirements, and safety constraints; and
transmitting a control instruction to an intermediary charging interface (ICI) coupled directly to a utility revenue meter socket the ICI having a controllable current interrupt switch on an outer surface of the ICI to selectively enable or disable electrical power delivery to the electric vehicle.

25. An electric vehicle charging interface device, comprising:
a controllable power circuit disposed directly on a utility panel connection, having a meter attachment fixture or a meter integrated therein, and providing power to an electric vehicle charging load;
a communication interface configured to exchange data with a platform system; and
a controller configured to open or close the controllable power circuit in response to control instructions received from the platform system.

26. A method for managing electrical current in an electric power interface system, comprising:
monitoring, by an interface system directly coupled to a utility power panel having a controllable breaker disposed on an exterior of the interface system and a communication-capable controller coupled to the breaker, real-time electrical load conditions;
determining an available electrical capacity of the utility power panel based on the monitored real-time electrical load conditions; and
dynamically regulating via the communication-capable controller a flow of electrical current through the interface system in real time in accordance with available electrical capacity.

27. The method of claim 26, further comprising determining an authorization condition to enable the flow of electrical current.

28. The method of claim 26, wherein determining the available electrical capacity comprises subtracting a measured load from a predetermined panel capacity limit.

29. The method of claim 26, wherein dynamically regulating the flow of electrical current comprises at least one of limiting, throttling, and modulating the flow of electrical current.

30. The method of claim 26, further comprising:
receiving at least one of a demand response and load-shedding commands from a grid management system; and
altering a condition state of the controllable breaker in response to the commands.

31. The method of claim 26, further comprising, altering a condition state of the controllable breaker in response to detection of the abnormal electrical condition.

32. An electrical meter-interface device, comprising:
a housing configured to be installed between a utility revenue meter and a utility meter socket of an electrical service panel;
a plurality of electrical conductors extending through the housing and configured to electrically couple the utility revenue meter to the utility meter socket;
an overcurrent protection device mounted on an exterior of the housing and electrically coupled to at least one of the plurality of electrical conductors; and
an external power interface electrically coupled to the overcurrent protection device and configured to supply electrical power to an externally located device,
wherein the electrical meter-interface device provides external electrical power independent of branch circuit breakers within the electrical service panel.

33. An electrical meter-interface device, comprising:
a housing configured to couple between a utility revenue meter and a utility meter socket;
electrical conductors extending through the housing;
an integral breaker receptacle disposed within the housing and electrically coupled to at least one of the electrical conductors;
an external power interface electrically coupled to the integral breaker receptacle,
wherein the integral breaker receptacle is configured to receive a removable circuit breaker selected to provide overcurrent protection for power delivered through the external power interface.

34. An electrical meter-interface device, comprising:
a housing configured for installation between a utility revenue meter and a utility meter socket;
electrical conductors extending through the housing;
an overcurrent protection device coupled to at least one of the electrical conductors; and
an environmentally sealed external receptacle mounted on the housing and electrically coupled to the overcurrent protection device,
wherein the external receptacle is configured to provide electrical power to at least one external load without modification of the electrical service panel.

35. An electrical meter-interface device, comprising:
a housing configured to couple between a utility revenue meter and a utility meter socket;
electrical conductors extending through the housing; and
an external power interface electrically coupled to the electrical conductors,
wherein a meter coupling axis of the housing is laterally offset from a panel coupling axis of the housing such that an axial protrusion of the device from the electrical service panel is reduced.

36. An electrical power interface device, comprising:
a housing configured to be installed at a utility meter connection;
a controllable switching element disposed within the housing and electrically coupled to conductors supplying power through the housing;
at least one electrical sensor configured to monitor a load condition of an associated electrical service panel; and
a controller configured to dynamically regulate current flow through the controllable switching element based on an available electrical capacity of the electrical service panel.

37. An electrical meter-interface device, comprising:
a housing configured to be installed between a utility revenue meter and a utility meter socket;
an overcurrent protection device supported by the housing and connected to electrical conductors within the housing;
an external power interface coupled to the overcurrent protection device; and
a breakaway coupling configured to mechanically release an external power cable from the housing when subjected to a tensile load above a threshold,
wherein release of the breakaway coupling interrupts electrical power delivery through the external power interface.

38. The device of claim 37, wherein the breakaway coupling comprises at least one of a magnetic coupling, snap-fit coupling, latching coupling, or twist-release coupling.

39. The device of claim 37, wherein the breakaway coupling is configured such that mechanical separation of the external power cable occurs prior to transfer of damaging force to electrical terminations within the housing.

40. The device of claim 37, further comprising a cable support assembly coupled to the housing and configured to provide strain relief by supporting the external power cable and reducing tensile load transferred to the external power interface.

41. An electrical power interface device for installation at a service entrance of an electrical installation, comprising:
a housing configured to be installed between a utility revenue meter and a meter socket of an electrical service panel;
electrical conductors arranged within the housing for conducting electrical power between the utility revenue meter and the electrical service panel;
an external power interface electrically coupled to at least one of the electrical conductors;
an overcurrent protection device arranged between the electrical conductors and the external power interface;
a mechanical breakaway coupling associated with the external power interface and configured to mechanically separate an external power cable when subjected to a tensile force exceeding a predetermined threshold; and
an interruption mechanism configured such that mechanical separation of the breakaway coupling directly triggers electrical interruption of power flow to the external power interface at the service entrance, thereby preventing exposure of energized conductors.

42. The device of claim 37, wherein the external power interface comprises a retractable electric vehicle charging cable assembly, the retractable electric vehicle charging cable assembly comprising:
a charging cable electrically coupled to the external power interface;
a retraction mechanism configured to selectively extend and retract the charging cable; and
a cable termination configured to mate with an electric vehicle charging inlet.

43. The device of claim 42, wherein the retraction mechanism comprises at least one of a spring-biased reel, motor-driven reel, gravity-assisted reel, or powered winding mechanism.

44. The device of claim 42, wherein the retractable electric vehicle charging cable assembly is configured to at least one of maintain electrical disconnection when the charging cable is fully retracted and upon extension beyond a predetermined length enables electrical connection to the external power interface.
